(19) United States
(12) Patent Application Publication
(10) Pub. No.: US 2026/0068368 A1
(43) Pub. Date: Mar. 5, 2026

(54) DISPLAY MODULE AND MANUFACTURING METHOD THEREOF

(71) Applicant: SAMSUNG ELECTRONICS CO, LTD., Suwon-si (KR)

(72) Inventors: Soonmin HONG, Suwon-si (KR); Yeonghyeon SEO, Suwon-si (KR); Sera KWON, Suwon-si (KR); Hyuntae JANG, Suwon-si (KR); Jonghoon JUNG, Suwon-si (KR)

(73) Assignee: SAMSUNG ELECTRONICS CO, LTD., Suwon-si (KR)

(21) Appl. No.: 19/364,126

(22) Filed: Oct. 21, 2025

Related U.S. Application Data
(63) Continuation of application No. PCT/KR2025/012846, filed on Aug. 22, 2025.

(30) Foreign Application Priority Data
Aug. 30, 2024 (KR) 10-2024-0117776

(51) Int. Cl. H10H 20/831; H10H 20/01; H10H 20/857; H10H 29/85

(52) U.S. Cl. CPC H10H 20/8314; H10H 20/017; H10H 20/032; H10H 20/0364; H10H 20/857; H10H 29/8508

(57) ABSTRACT

A display module may include: a substrate including a first pad and a common electrode pad; a light emitting diode including a first electrode connected to the first pad, and a second electrode; a conductive connector connected to the common electrode pad, and connecting the second electrode to the common electrode pad; an adhesive layer on the substrate; and a conductive layer on the adhesive layer, the conductive layer connecting the second electrode to the conductive connector, wherein the second electrode is on a side surface of the light emitting diode, the side surface being between a light emitting surface of the light emitting diode and a bottom surface of the light emitting diode that is opposite to the light emitting surface, and the light emitting surface is exposed from the conductive layer, and the conductive layer surrounds the second electrode of the light emitting diode.

### CROSS-REFERENCE TO RELATED APPLICATION(S)

This application is a bypass continuation application of International Patent Application No. PCT/KR2025/012846, filed on Aug. 22, 2025, which claims priority to Korean Patent Application No 10-2024-0117776, filed on Aug. 30, 2024, in the Korean Intellectual Property Office, the disclosure of each of which is incorporated by reference herein in its entirety.

### BACKGROUND

### 1. Field

The disclosure relates to a display module and a manufacturing method thereof.

### 2. Description of Related Art

Recently, technology for light-emitting diodes (LEDs) based on compound semiconductors such as GaN, GaAs, and GaP has been developing rapidly. With the technology development of such LEDs, the interest in LED display devices utilizing panel configuration technology that directly mounts (e.g., transfers) LEDs that emit light in the red (R), green (G), and blue (B) wavelength bands on a circuit board has been increasing. In particular, miniaturization of LEDs is essential for outputting high-quality images in LED display devices, and thus, much development infrastructure is being invested to perfect a micro light emitting diode having an ultra-small size of 100 micrometers or less.

### SUMMARY

According to an aspect of the disclosure, a display module may include: a substrate including a first pad and a common electrode pad; a light emitting diode including a first electrode connected to the first pad, and a second electrode; a conductive connector connected to the common electrode pad, and connecting the second electrode to the common electrode pad; an adhesive layer on the substrate; and a conductive layer on the adhesive layer, the conductive layer connecting the second electrode to the conductive connector, wherein the second electrode of the light emitting diode is on a side surface of the light emitting diode, the side surface being between a light emitting surface of the light emitting diode and a bottom surface of the light emitting diode, the bottom surface being opposite to the light emitting surface, and wherein the light emitting surface of the light emitting diode is exposed from the conductive layer, and the conductive layer surrounds the second electrode of the light emitting diode.

According to an aspect of the disclosure, a method of manufacturing a display module may include: providing an adhesive layer on a first surface of a substrate; transferring a light emitting diode onto the adhesive layer; transferring a conductive connector onto the adhesive layer; connecting a first electrode of the light emitting diode to a first pad of the substrate and connecting a third electrode to a common electrode pad of the substrate, the third electrode being on a bottom portion of the conductive connector, and the connecting the first electrode and the connecting the third electrode including heat-pressing the light emitting diode and the conductive connector to the substrate; and forming a conductive layer on the adhesive layer, wherein a light emitting surface of the light emitting diode is exposed from the conductive layer, and the conductive layer connects a second electrode of the light emitting diode and a fourth electrode, the fourth electrode being on a side surface of the conductive connector.

According to an aspect of the disclosure, a display module may include: a substrate including a first pad and a common electrode pad; a light emitting diode including a first electrode connected to the first pad; a conductive connector connected to the common electrode pad; an adhesive layer on the substrate; and a conductive layer on the adhesive layer, the conductive layer connected to a side surface of the light emitting diode, the side surface being between a light emitting surface of the light emitting diode and a bottom surface of the light emitting diode, the bottom surface being opposite to the light emitting surface, wherein the side surface of the light emitting diode is connected to the common electrode pad of the substrate by the conductive layer and the conductive connector.

### BRIEF DESCRIPTION OF DRAWINGS

The above and other aspects, features, and advantages of certain embodiments of the present disclosure will be more apparent from the following description taken in conjunction with the accompanying drawings, in which:

FIG. 1 is a front view illustrating a display module according to an embodiment of the disclosure;

FIG. 2 is an enlarged view illustrating a portion A of a display module according to an embodiment of the disclosure;

FIG. 3 is a cross-sectional view along a line B-B′ illustrated in FIG. 2, and illustrates pixels according to an embodiment of the disclosure;

FIG. 4 is a cross-sectional view illustrating a first micro light emitting diode of the display module according to an embodiment of the disclosure;

FIG. 5 is a cross-sectional view illustrating the first micro light emitting diode of the display module according to an embodiment of the disclosure;

FIGS. 6 to 8 are diagrams illustrating various shapes of a second electrode provided on a side surface of the first micro light emitting diode according to an embodiment of the disclosure;

FIGS. 9 and 10 are diagrams describing a method of manufacturing a micro light emitting diode according to an embodiment of the disclosure;

FIG. 11 is a flowchart for describing a method of manufacturing a display module 30 according to an embodiment of the disclosure;

FIGS. 12 to 17 are diagrams describing a method of manufacturing a display module according to an embodiment;

FIGS. 18, 19, and 20 are diagrams describing the method of manufacturing a display module according to an embodiment of the disclosure;

FIGS. 21, 22, and 23 are diagrams describing the method of manufacturing a display module according to an embodiment of the disclosure;

FIGS. 24 and 25 are diagrams describing the method of manufacturing a display module according to an embodiment of the disclosure;

FIG. 26 is a diagram describing the method of manufacturing a display module according to an embodiment of the disclosure;

FIGS. 27 and 28 are diagrams describing the method of manufacturing a display module according to an embodiment of the disclosure;

FIGS. 29, 30, and 31 are diagrams describing the method of manufacturing a display module according to an embodiment of the disclosure;

FIGS. 32, 33, and 34 are diagrams illustrating the method of manufacturing a display module according to an embodiment of the disclosure;

FIGS. 35, 36, and 37 are diagrams describing the method of manufacturing a display module according to an embodiment of the disclosure;

FIG. 38 is a cross-sectional view illustrating a pixel according to an embodiment of the disclosure; and

FIG. 39 is a block diagram illustrating a display device according to an embodiment of the disclosure.

### DETAILED DESCRIPTION

Non-limiting example embodiments of the disclosure are described below with reference to the accompanying drawings. However, it is to be understood that the disclosure is not limited to the example embodiments, and includes all modifications, equivalents, and substitutions according to one or more embodiments of the disclosure. Throughout the accompanying drawings, similar components will be denoted by similar reference numerals.

In describing the disclosure, when it is determined that a detailed description for known functions or configurations related to the disclosure may unnecessarily obscure the gist of the disclosure, the detailed description therefor may be omitted. In addition, one or more embodiments according to the disclosure may be modified in several different forms, and the spirit and scope of the disclosure is not limited to the following example embodiments. Rather, these example embodiments make the disclosure thorough and complete, and are provided to completely describe the spirit of the disclosure to those skilled in the art.

Terms used in the disclosure are used only to describe specific non-limiting example embodiments rather than limiting the scope of the disclosure. Singular expressions are intended to include plural expressions unless the context clearly indicates otherwise.

In the disclosure, an expression “have,” “may have,” “include,” “may include,” “comprise,” “may comprise,” or the like, indicates existence of a corresponding feature (e.g., a numerical value, a function, an operation, a component such as a part, or the like), and does not exclude existence of an additional feature.

In the disclosure, an expression “A or B,” “at least one of A and/or B,” “one or more of A and/or B,” or the like, may include all possible combinations of items enumerated together. For example, “A or B,” “at least one of A and B,” or “at least one of A or B” may indicate all of (1) a case in which only A is included, (2) a case in which only B is included, and (3) a case in which both of A and B are included.

Expressions “first,” “second,” “1st” or “2nd” or the like, used in the disclosure may indicate various components regardless of a sequence and/or importance of the components, will be used only in order to distinguish one component from the other components, and do not limit the corresponding components.

An expression “configured (or set) to” used in the disclosure may be replaced by an expression “suitable for,” “having the capacity to,” “designed to,” “adapted to,” “made to,” or “capable of” depending on a situation. A term “configured (or set) to” may not necessarily mean “specifically designed to” in hardware.

In the disclosure, a “module” or a “˜er/or” may perform at least one function or operation, and be implemented by hardware or software or be implemented by a combination of hardware and software. In addition, a plurality of “modules” or a plurality of “units” may be integrated in at least one module and be implemented by at least one processor except for a “module” or a “unit” that needs to be implemented by specific hardware.

Meanwhile, various elements and regions in the drawings are schematically illustrated. Therefore, embodiments of the disclosure are not limited by relatively sizes or intervals illustrated in the accompanying drawings.

Hereinafter, one or more non-limiting example embodiments of the disclosure will be described in detail with reference to the accompanying drawings so that those skilled in the art to which the disclosure pertains may easily practice the disclosure.

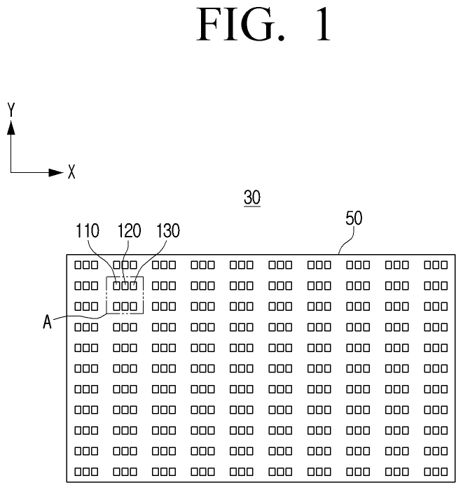

FIG. 1 is a front view illustrating a display module 30 according to one or more embodiments of the disclosure. Hereinafter, a plurality of light emitting diodes mounted on a substrate 50 of the display module 30 may be micro light emitting diodes having a size of 100 μm or less or 30 μm or less.

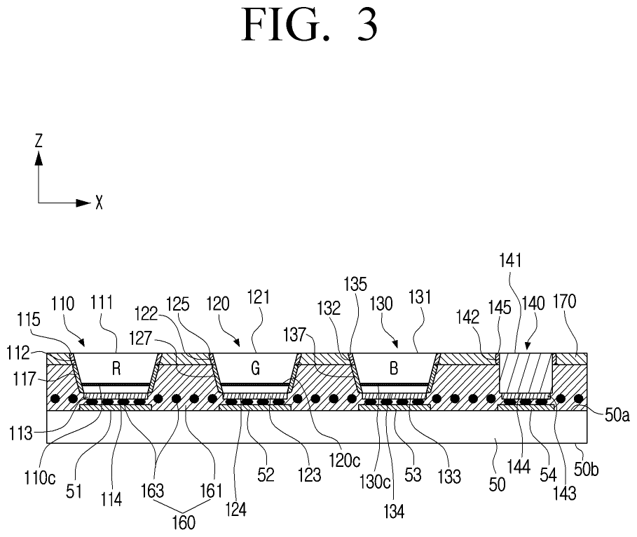

Referring to FIG. 1, the display module 30 may include the substrate 50, and a first micro LED 110, a second micro LED 120, and a third micro LED 130 that are arranged on the substrate 50. The first micro LED 110, the second micro LED 120, and the third micro LED 130 may form one pixel. Each of the first micro LED 110, the second micro LED 120, and the third micro LED 130 may be referred to as a sub-pixel. The substrate 50 may have a plurality of pixel areas provided in a roughly lattice shape on a first surface 50a (see FIG. 3) of the substrate 50. Each of the plurality of pixel areas may be provided with one pixel.

The first micro LED 110, the second micro LED 120, and the third micro LED 130 may be arranged in a lattice pattern with a constant pitch on a top surface of the substrate 50. A size (e.g., width×length×height) of each of the first micro LED 110, the second micro LED 120, and the third micro LED 130 may be, for example, 30 μm×30 μm×10 μm or less. Here, the width×length may be areas of light emitting surfaces 111, 121, and 131 of each of the first micro LED 110, the second micro LED 120, and the third micro LED 130.

The width and length of the first micro LED 110, the second micro LED 120, and the third micro LED 130 may be the same as each other, but are not limited thereto. The width and height of the first micro LED 110, the second micro LED 120, and the third micro LED 130 may not be the same as each other. For example, the width×height of the first micro LED 110, the second micro LED 120, and the third micro LED 130 may be 30 μm×10 μm or 10 μm×30 μm. For example, when the width and height of the first micro LED 110, the second micro LED 120, and the third micro LED 130 are 30 μm×30 μm or less, the heights of the first micro LED 110, the second micro LED 120, and the third micro LED 130 may be configured to be approximately 10 μm or less.

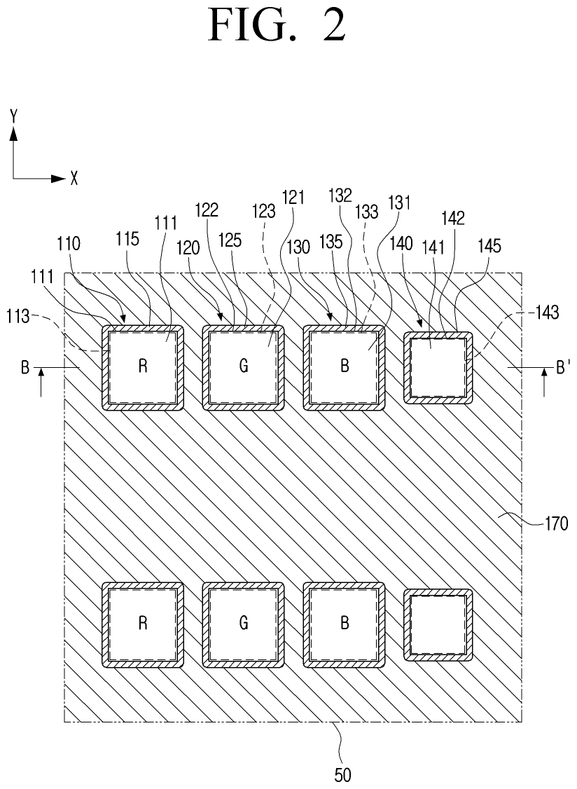

FIG. 2 is an enlarged view illustrating a portion A of the display module 30 according to an embodiment of the disclosure. FIG. 3 is a cross-sectional view along a line B-B′ illustrated in FIG. 2, and illustrates pixels according to an embodiment of the disclosure.

Referring to FIGS. 2 and 3, the first micro LED 110, the second micro LED 120, and the third micro LED 130 included in one pixel may emit light of different wavelength bands from each other. For example, the first micro LED 110 may emit red light. The second micro LED 120 may emit green light. The third micro LED 130 may emit blue light.

The sizes of the first micro LED 110, the second micro LED 120, and the third micro LED 130 may all be substantially the same, but are not limited thereto. The sizes of the first micro LED 110, the second micro LED 120, and the third micro LED 130 may have different sizes depending on the wavelength bands to which they are applied, respectively.

In the case of a pentile array, the sizes of the first micro LED 110, the second micro LED 120, and the third micro LED 130, each of which includes four micro LEDs in one pixel, may have different sizes depending on the wavelength band to which they are applied. The first micro LED 110 that emits red light may have a first size. The third micro LED 130 that emits blue light may have a second size that is smaller than the first size. The second micro LED 120 that emits green light may have a third size that is smaller than the second size. There may be two second micro LEDs 120. In this case, a total of four micro LEDs may be included in one pixel.

The arrangement order of the first micro LED 110, the second micro LED 120, and the third micro LED 130 is described as being arranged from left to right, but is not limited thereto. For example, the first micro LED 110, the second micro LED 120, and the third micro LED 130 may be arranged sequentially from right to left. The second micro LED 120, the third micro LED 130, and the first micro LED 110 may be arranged sequentially from right to left.

Each of the first micro LED 110, the second micro LED 120, and the third micro LED 130 may include first electrodes 113, 123, and 133 and second electrodes 115, 125, and 135 electrically connected to a plurality of TFT circuits provided on the substrate 50. The first electrodes 113, 123, and 133 may be an anode electrode, and the second electrodes 115, 125, and 135 may be a cathode electrode.

The first electrodes 113, 123, and 133 may be provided on bottom surfaces 114, 124, and 134 of the first micro LED 110, the second micro LED 120, and the third micro LED 130. Here, the bottom surfaces 114, 124, and 134 of the first micro LED 110, the second micro LED 120, and the third micro LED 130 may be an opposite surface with respect to the light emitting surface 111, 121, and 131 of the first micro LED 110, the second micro LED 120, and the third micro LED 130.

Second electrodes 115, 125, and 135 may be provided on side surfaces 112, 122, and 132 of the first micro LED 110, the second micro LED 120, and the third micro LED 130. The second electrodes 115, 125, and 135 may surround the side surfaces 112, 122, and 132 of the first micro LED 110, the second micro LED 120, and the third micro LED 130 in a closed loop shape as illustrated in FIG. 2. The second electrodes 115, 125, and 135 may be electrically connected to a conductive layer 170.

The conductive layer 170 may be electrically connected to a conductive connector 140 connected to a common electrode pad 54 of the substrate 50. Accordingly, the second electrodes 115, 125, and 135 may be electrically connected to the common electrode pad 54 of the substrate 50.

The conductive layer 170 may be applied to a top surface of an adhesive layer 160. The conductive layer 170 may be cured to contact and electrically connect the second electrodes 115, 125, and 135 of the first micro LED 110, the second micro LED 120, the third micro LED 130, and a fourth electrode 145 of the conductive connector 140, respectively. The conductive layer 170 may include ink, paste, or a semi-cured film containing conductive particles. The conductive particles may include at least one from among Ag, Au, Cu, In, Sn, Ni, Co, Cr, Fe, Mo, and graphene. The conductive layer 170 may be formed on the adhesive layer 160 by at least one from among inkjet printing, spray coating, spin coating, and slot die coating.

The conductive connector 140 may have a third electrode 143 disposed on a bottom surface 144 of the conductive connector 140. The third electrode 143 may be electrically connected to the common electrode pad 54 of the substrate 50. The conductive connector 140 may have the fourth electrode 145 arranged on a side surface 142 of the conductive connector 140. The fourth electrode 145 may be electrically connected to the conductive layer 170.

According to some embodiments, the conductive connector 140 may not include the third electrode 143 and the fourth electrode 145. In this case, the bottom surface 144 of the conductive connector 140 may be directly electrically connected to the common electrode pad 54 of the substrate 50, and the side surface 142 of the conductive connector 140 may be directly electrically connected to the conductive layer 170. In this case, the conductive connector 140 may be formed of a material that may minimize electrical resistance (e.g., ohmic resistance) for the common electrode pad 54 and the conductive layer 170.

Reflective layers 117, 127, and 137 may be provided on the side surfaces 112, 122, and 132 of the first micro LED 110, the second micro LED 120, and the third micro LED 130. In this case, the reflective layers 117, 127, and 137 may be arranged on lower sides of the second electrodes 115, 125, and 135. The reflective layers 117, 127, and 137 may be in contact with the second electrodes 115, 125, and 135, but is not limited thereto. For example, upper ends of the reflective layers 117, 127, and 137 and lower ends of the second electrodes 115, 125, and 135 may be spaced apart from each other, so the reflective layers 117, 127, and 137 and the second electrodes 115, 125, and 135 are not in contact with each other. In this way, the reflective layers 117, 127, and 137 and the second electrodes 115, 125, and 135 may be provided together on the side surfaces 112, 122, and 132 of the first micro LED 110, the second micro LED 120, and the third micro LED 130.

The reflective layers 117, 127, and 137 may reflect light emitted from active layers 110c, 120c, and 130c of the first micro LED 110, the second micro LED 120, and the third micro LED 130 to the light emitting surfaces 111, 121, and 131. The reflective layers 117, 127, and 137 may include a distributed bragg reflector (DBR). The DBR may be deposited in the form of a thin film on the side surfaces 112, 122, and 132 of the first micro LED 110, the second micro LED 120, and the third micro LED 130 by, for example, a method such as chemical vapor deposition (CVD) or atomic layer deposition (ALD). The DBR may include a multilayer structure formed by alternately stacking high refractive index materials (e.g., TiO2, GaN) and low refractive index materials (e.g., SiO2, Al2O3). For example, thicknesses of each layer of the DBR may be formed to correspond to ¼ of a specific wavelength to be reflected. Accordingly, the DBR may improve reflectivity by satisfying resonance conditions by reflecting light of a specific wavelength from multiple layers. The optical performance of the first micro LED 110, the second micro LED 120, and the third micro LED 130 may be improved by the reflective layers 117, 127, and 137.

The adhesive layer 160 may be attached to the first surface 50a of the substrate 50. The adhesive layer 160 may include, for example, an anisotropic conductive film (ACF) or an anisotropic conductive paste. The adhesive layer 160 may include a non-conductive resin layer 161 (e.g., a polymer-based adhesive) having adhesiveness and a plurality of conductive balls 163 (e.g., fine conductive balls) uniformly arranged within the non-conductive resin layer 161.

The non-conductive resin layer 161 of the adhesive layer 160 may be heated by heat when the first micro LED 110, the second micro LED 120, and the third micro LED 130 are heat-pressed to the substrate 50. In this case, the first micro LED 110, the second micro LED 120, and the third micro LED 130 may be introduced into the inside from the surface of the non-conductive resin layer 161. When the non-conductive resin layer 161 is cured, the first micro LED 110, the second micro LED 120, and the third micro LED 130 may be firmly fixed to the substrate 50.

The non-conductive resin layer 161 may have a color with high light absorption (e.g., black or a black-based color). The non-conductive resin layer 161 may absorb external light (e.g., light emitted from natural light or indoor lights around the display module 30). Accordingly, the boundary between adjacent micro LEDs may be clearly created to reduce interference from surrounding light sources or light reflection, thereby improving the screen contrast ratio and clarity of the display module 30. The non-conductive resin layer 161 may separate the light emitted from adjacent first micro LED 110, the second micro LED 120, and the third micro LED 130 from each other, thereby improving the spreading to adjacent micro LEDs.

The non-conductive resin layer 161 may be configured to be transparent. In this case, a black matrix may be provided on the non-conductive resin layer 161. The black matrix may be configured to surround the light emitting surfaces 111, 121, and 131 of the first micro LED 110, the second micro LED 120, and the third micro LED 130 so as not to cover the light emitting surfaces 111, 121, and 131.

A plurality of conductive balls 163 of the adhesive layer 160 may electrically connect the first electrodes 113, 123, and 133 of the first micro LED 110, the second micro LED 120, and the third micro LED 130 and the first pad 51, the second pad 52, and the third pad 53 of the substrate 50. The plurality of conductive balls 163 may be formed of an insulating material (e.g., synthetic resin, glass, ceramic) and a conductive metal (e.g., Au, Ag, Cu, Ni) coated on the surface of the insulating material, or may be formed of a carbon-based material such as graphene or carbon nanotubes. The conductive ball 163 may have a size of about 2 to 10 μm. The conductive ball 163 may allow current to flow only in a thickness direction of the adhesive layer 160 (e.g., in the vertical direction of the film).

The substrate 50 may include a plurality of thin film transistor (TFT) circuits. The substrate 50 may include the first surface 50a on which the first micro LED 110, the second micro LED 120, and the third micro LED 130 are mounted, and a second surface 50b of the substrate 50 that is opposite to the first surface 50a. A power supply circuit for supplying power to the plurality of TFT circuits, a data driver, a gate driver, and a timing controller for controlling each of the drive drivers may be arranged on the second surface 50b of the substrate 50.

The TFT circuit may include a plurality of TFTs for driving the first micro LED 110, the second micro LED 120, and the third micro LED 130. A plurality of TFTs may be provided in one pixel area. The TFT circuit may be located on an inner side of the substrate 50. For example, the TFT circuit may be formed in an area adjacent to the first surface 50a of the substrate 50. Without being limited thereto, the TFT circuit may be manufactured in a separate film form and attached to the first surface 50a of the substrate 50. The first pad 51, the second pad 52, the third pad 53 and the common electrode pad 54 arranged on the first surface 50a of the substrate 50 may be electrically connected to the plurality of TFTs included in the TFT circuit. The TFT is not limited to a specific structure or type. For example, the TFT may be implemented as a low-temperature polycrystalline silicon TFT (LTPS TFT), an oxide TFT, an a-silicon (poly silicon) (a-Si) TFT, an organic TFT, a graphene TFT, etc. The TFT circuit may include only a P-type (or N-type) metal oxide semiconductor field effect transistor (MOSFET) in a complementary metal oxide semiconductor (CMOS) process on a Si wafer.

The first micro LED 110, the second micro LED 120, and the third micro LED 130 may have differences in emitting light of different colors, but their overall structures may be substantially the same. Hereinafter, the structure of the first micro LED 110 will be described.

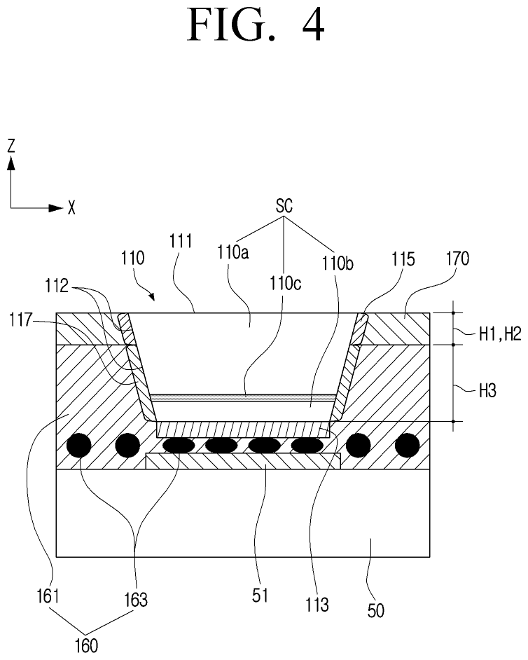

FIG. 4 is a cross-sectional view illustrating the first micro LED 110 of the display module 30 according to an embodiment of the disclosure.

Referring to FIG. 4, the first micro LED 110 may include a semiconductor component SC, a first electrode 113, a second electrode 115, and a reflective layer 117.

The semiconductor component SC may include an n-type semiconductor layer 110a, a p-type semiconductor layer 110b, and an active layer 110c. Each of the n-type semiconductor layer 110a and the p-type semiconductor layer 110b may be implemented as a compound semiconductor of group III-V, group II-VI, etc. For example, each of the n-type semiconductor layer 110a and the p-type semiconductor layer 110b may be implemented as a nitride semiconductor. Each of the n-type semiconductor layer 110a and the p-type semiconductor layer 110b may be an n-GaN semiconductor layer and a p-GaN semiconductor layer, respectively. However, each of the n-type semiconductor layer 110a and the p-type semiconductor layer 110b is not limited thereto, and may be formed of various materials according to various characteristics required for the micro LED.

The n-type semiconductor layer 110a may be a semiconductor in which free electrons are used as carriers for transferring charges, and may be made by doping an n-type dopant such as Si, Ge, Sn, or Te. The p-type semiconductor layer 110b may be a semiconductor in which holes are used as carriers for transferring charges, and may be made by doping with a p-type dopant such as Mg, Zn, Ca, or Ba.

The n-type semiconductor layer 110a may include a light emitting surface 111 that acts as a passage through which light generated from the active layer 110c is emitted to the outside of the micro LED 110. The light emitting surface 111 may be approximately flat and may be formed approximately parallel to the active layer 110c. In the disclosure, the “top surface of the semiconductor component SC” and the “light emitting surface of the semiconductor component SC” may be the same as the “light emitting surface 111 of the first micro LED 110, the second micro LED 120, and the third micro LED 130.” A “side surface of the semiconductor component SC” may be the same as the “side surface 112 of the first micro LED 110, the second micro LED 120, and the third micro LED 130.”

The n-type semiconductor layer 110a may be electrically connected to the second electrode 115. The second electrode 115 may be formed of Al, Ti, Cr, Ni, Pd, Ag, Ge, and Au, or an alloy thereof. Electrically conductive oxides such as ITO (indium tin oxide) and ZnO may be used for ohmic contacts between the second electrode 115 and the n-type semiconductor layer 110a.

The p-type semiconductor layer 110b may be electrically connected to the first electrode 113. The first electrode 113 may be formed of one of Al, Ti, Cr, Ni, Pd, Ag, Ge, and Au, or an alloy thereof. The indium tin oxide (ITO) and ZnO such as the electrically conductive oxides may be used for ohmic contacts between the first electrode 113 and the p-type semiconductor layer 110b.

The n-type semiconductor layer 110a, the p-type semiconductor layer 110b, and the active layer 110c may be composed of various semiconductors having band gaps corresponding to specific regions within spectrum. For example, the first micro LED 110 having an optical wavelength of 600 to 750 nm (red) may include one or more layers based on an AlInGaP-based semiconductor. The second micro LED 120 and the third micro LED 130, each having an optical wavelength of 500 to 570 nm (green) and an optical wavelength of 450 to 490 nm (blue), may include one or more layers based on an AlInGaN-based semiconductor.

The active layer 110c may be located between the n-type semiconductor layer 110a and the p-type semiconductor layer 110b. The active layer 110c may be a layer where electrons, which are carriers of the n-type semiconductor layer 110a, and holes, which are carriers of the p-type semiconductor layer 110b, meet. When electrons and holes meet in the active layer 110c, a potential barrier is formed as the electrons and holes recombine. In this case, when the electrons and holes transition to a lower energy level by overcoming the potential barrier according to the voltage applied to the first micro LED 110, the light of the corresponding wavelength (e.g., red light) is emitted. The active layer 110c may include a multi-quantum well structure, but embodiments of the disclosure are not limited thereto. For example, the active layer 110c may include a single quantum well or a quantum dot structure. When the active layer 110c includes a multi-quantum well structure, the well layer/barrier layer of the active layer 110c may be formed with a structure such as InGaN/GaN, InGaN/InGaN, GaAs/AlGaAs, but is not limited to this structure. The number of quantum wells included in the active layer 110c is also not limited to a specific number.

The side surface 112 of the semiconductor component SC may be configured to slope from the light emitting surface 111 (e.g., top surface) of the semiconductor component SC to the bottom surface, which is the opposite side of the light emitting surface 111 (e.g., top surface) of the semiconductor component SC. For example, the side surface 112 of the semiconductor component SC may form an acute angle with respect to the light emitting surface 111 (e.g., top surface) of the semiconductor component SC. However, embodiments of the disclosure are not limited thereto, and the side surface 112 of the semiconductor component SC may form an obtuse angle with respect to the light emitting surface 111 (e.g., top surface) of the semiconductor component SC.

The second electrode 115 and the reflective layer 117 may be provided together on the side surface 112 of the semiconductor component SC. As illustrated in FIG. 4, the second electrode 115 may be arranged on the top portion of the side surface 112 of the semiconductor component SC, and the reflective layer 117 may be arranged on the bottom portion of the side surface 112 of the semiconductor component SC. In this case, a height H1 of the second electrode 115 may be substantially the same as a height H2 of the conductive layer 170. The light emitting surface 111 (e.g., top surface) of the semiconductor component SC may be completely exposed without being covered by the second electrode 115 or the conductive layer 170.

The height H1 of the second electrode 115 may be smaller than a height H3 of the reflective layer 117. However, embodiments of the disclosure are not limited thereto, and the height H1 of the second electrode 115 may be smaller than or equal to the height H3 of the reflective layer 117. In this case, the height H1 of the second electrode 115 may have a height such that the second electrode 115 does not contact the active layer 110c and the p-type semiconductor layer 110b.

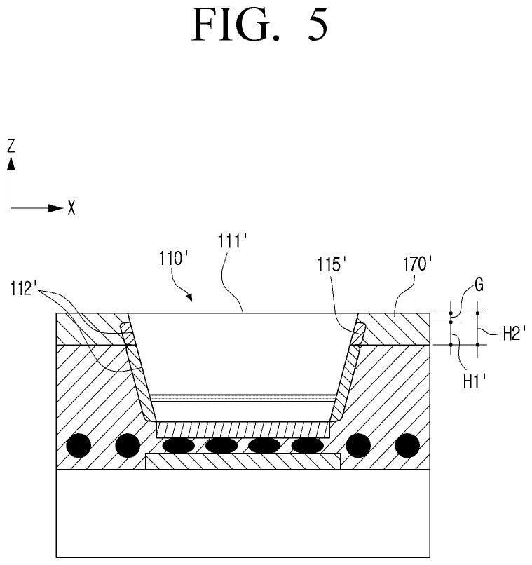

FIG. 5 is a cross-sectional view illustrating a first micro LED 110′ of the display module 30 according to an embodiment of the disclosure.

Referring to FIG. 5, the first micro LED 110′ may have a second electrode 115′ and a reflective layer 117′ covering the side surface 112′ of the first micro LED 110′. A height H1′ of the second electrode 115′ may be different from a height H2′ of the conductive layer 170′. For example, the height H1′ of the second electrode 115′ may be smaller than the height H2′ of the conductive layer 170′. In this case, an upper end of the second electrode 115′ may be located at a position that is lower by a constant distance G from the light emitting surface 111′ of the first micro LED 110′. A top surface of the conductive layer 170′ may be at substantially the same height as the height of the light emitting surface 111′ of the first micro LED 110′. The upper end of the second electrode 115′ may be covered by the conductive layer 170′. As illustrated in FIG. 5, even when the height H1′ of the second electrode 115′ is different from the height H2′ of the conductive layer 170′, the light emitting surface 111′ of the first micro LED 110′ may be completely exposed without being covered by the conductive layer 170′.

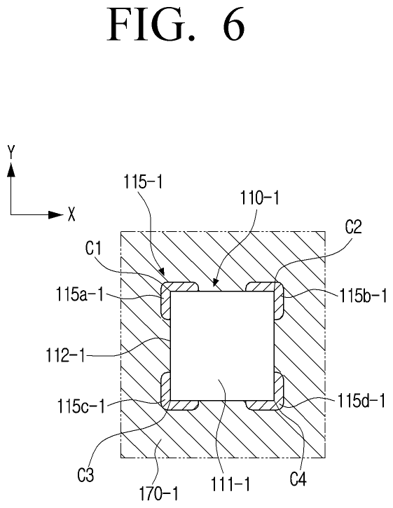

FIGS. 6, 7, and 8 are diagrams illustrating various shapes of the second electrode provided on the side surface of the first micro LED according to an embodiment of the disclosure.

Referring to FIG. 6, the first micro LED 110-1 may be formed by a plurality of second electrodes 115-1 provided on the side surface 112-1. For example, the second electrodes 115-1 may include a first portion 115a-1 (e.g., electrode), a second portion 115b-1 (e.g., electrode), a third portion 115c-1 (e.g., electrode), and a fourth portion 115d-1 (e.g., electrode) respectively arranged at a first corner C1, a second corner C2, a third corner C3, and a fourth corner C4 of the light emitting surface 111-1. In this case, the first portion 115a-1, the second portion 115b-1, the third portion 115c-1, and the fourth portion 115d-1 may be arranged symmetrically with respect to the center of the light emitting surface 111-1. According to embodiments, the plurality of second electrodes 115-1 may together be referred to as the second electrode 115.

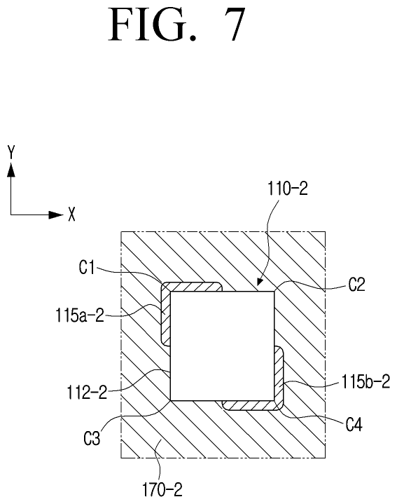

Referring to FIG. 7, the first micro LED 110-2 may be formed by a plurality of second electrodes provided on the side surface 112-2. For example, the second electrodes may include a first portion 115a-2 (e.g., electrode) and a second portion 115b-2 (e.g., electrode) respectively arranged at the first corner C1 and the fourth corner C4 diagonally arranged with respect to the first corner C1 among the first corner C1, the second corner C2, the third corner C3, and the fourth corner C4 of the light emitting surface 111-2. In this case, the first portion 115a-2 may be formed to have a constant length toward the second corner C2 and the third corner C3 adjacent to the first corner C1 of the light emitting surface 111-2. The second portion 115b-2 may be formed to have a constant length toward the second corner C2 and the third corner C3 adjacent to the fourth corner C4 of the light emitting surface 111-2. The first portion 115a-2 and the second portion 115b-2 of the second electrodes may be arranged diagonally symmetrically with respect to each other. According to embodiments, the plurality of second electrodes 115-2 may together be referred to as the second electrode 115.

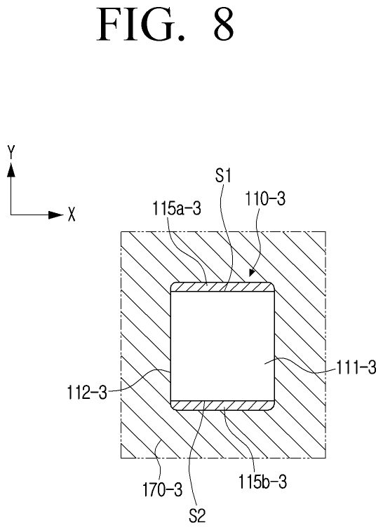

Referring to FIG. 8, the first micro LED 110-3 may be formed by a plurality of second electrodes provided on the side surface 112-3. For example, the second electrodes may include a first portion 115a-3 (e.g., electrode) and a second portion 115b-3 (e.g., electrode) respectively arranged on a first side S1 and a second side S2 of the light emitting surface 111-3, opposite to the first side S1. The first portion 115a-3 and the second portion 115b-3 of the second electrode may be arranged symmetrically with respect to a horizontal center axis of the light emitting surface 111-3 parallel to the X-axis of FIG. 8. According to embodiments, the plurality of second electrodes 115-3 may together be referred to as the second electrode 115.

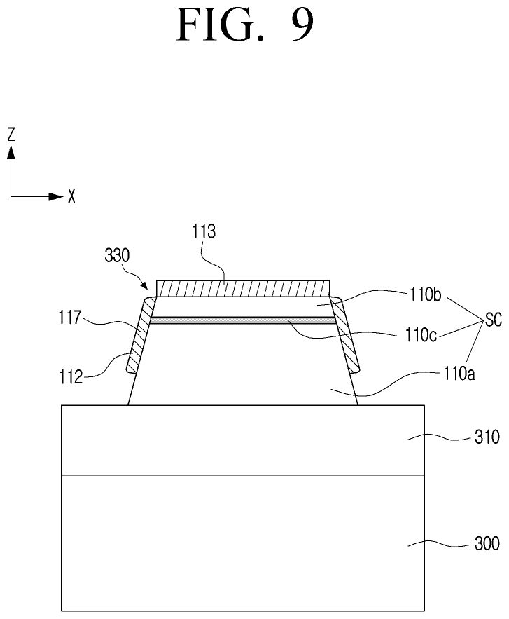

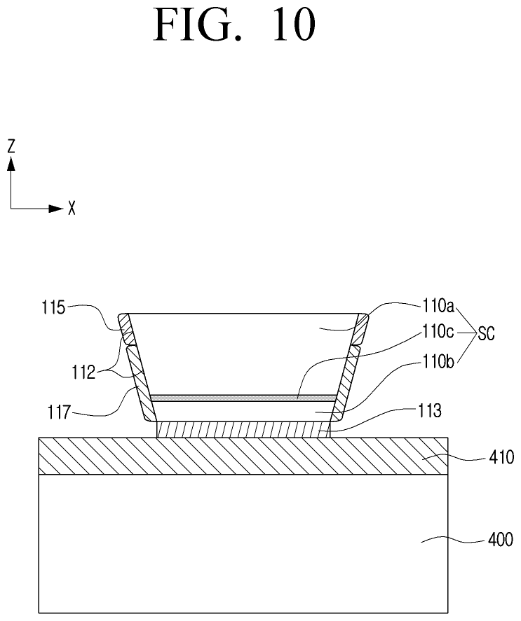

FIGS. 9 and 10 are diagrams describing a method of manufacturing a micro LED according to an embodiment of the disclosure.

Referring to FIG. 9, the plurality of micro LEDs (e.g., the first micro LED 110, the second micro LED 120, and the third micro LED 130) may be epi-grown on an epi substrate 300. The epi substrate 300 may be, for example, a sapphire (Al2O3) substrate. A buffer layer 310 may be formed on the epi substrate 300 to resolve a lattice mismatch between the epi substrate 300 and the epitaxial layer 330. The buffer layer 310 may be an aluminum nitride (AlN) or GaN buffer layer. The epitaxial layer 330 may be the semiconductor component SC that is a GaN (gallium nitride)-based compound semiconductor.

The epitaxial layer 330 may be grown on the buffer layer 310. The epitaxial layer 330 may be used as the semiconductor component SC of the first micro LED 110. The epitaxial layer 330 may be formed of n-type doped GaN, and include the n-type semiconductor layer 110a grown on the buffer layer 310 using a dopant such as silicon (Si). The n-type semiconductor layer 110a may be formed by a method such as metal organic chemical vapor deposition (MOCVD) or molecular beam epitaxy (MBE). The epitaxial layer 330 may include the active layer 110c grown on the n-type semiconductor layer 110a. The active layer 110c may be formed of, for example, indium gallium nitride (InGaN) and may have a multilayer quantum well structure. The quantum well structure may form a thin InGaN layer between GaN barrier layers. The wavelength of the emitted light may be controlled by adjusting the indium composition of the InGaN. In this case, the active layer 110c may obtain light emission characteristics of a desired wavelength by adjusting growth conditions (e.g., temperature, pressure, precursor concentration). The active layer 110c may emit light having one color (e.g., red, green, blue) depending on the light emission characteristics of the wavelength. The epitaxial layer 330 may include the p-type semiconductor layer 110b grown on the active layer 110c. The p-type semiconductor layer 110b may be formed of p-type doped GaN using a dopant such as magnesium (Mg). The p-type semiconductor layer 110b may supply holes so that the electrons and holes generated in the active layer 110c may recombine.

After surface-treating the top surface (e.g., the opposite surface from the surface contacting the active layer 110c) of the p-type semiconductor layer 110b, the first electrode 113 may be deposited on the top surface of the p-type semiconductor layer 110b.

An isolation process may be performed to form the semiconductor component SC of a certain size in order to use the epitaxial layer 330 as the plurality of micro LEDs. In this case, the side surface 112 of the semiconductor component SC may be formed to form an acute angle with respect to the light emitting surface 111. The reflective layer 117 may be deposited on the side surface 112 of the semiconductor component SC. In this case, the reflective layer 117 may be located on the bottom portion of the side surface 112 of the semiconductor component SC (e.g., an area adjacent to the first electrode 113 among the entire area of the side surface 112 of the semiconductor component SC).

Referring to FIG. 10, for example, the plurality of semiconductor components (SC) may be separated from the epi substrate 300 through a dicing process. The plurality of semiconductor components (SC) may be arranged at a predetermined interval so that the first electrode 113 is attached to an adhesive layer 410 on a first carrier substrate 400.

The second electrode 115 may be deposited on a top portion of the side surface 112 of the semiconductor components (SC) (e.g., an area adjacent to the light emitting surface 112). The second electrode 115 may be formed during the last step of the process of manufacturing the first micro LED 110, the second micro LED 120, and the third micro LED 130.

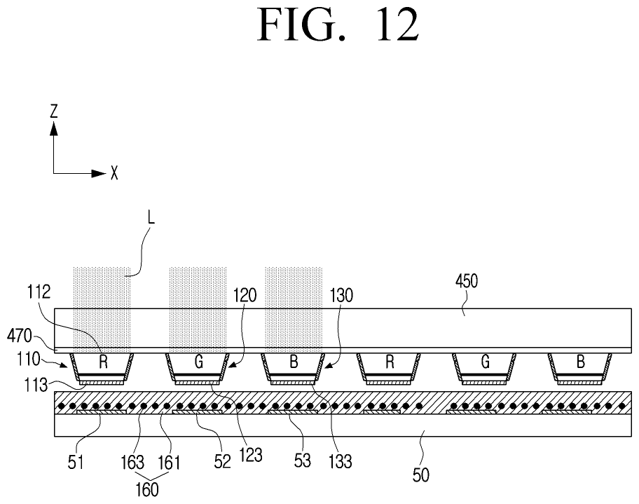

The first micro LED 110, the second micro LED 120, and the third micro LED 130 arranged on the first carrier substrate 400 may be transferred to a second carrier substrate 450 (see FIG. 12) before being transferred to the substrate 50. The first micro LED 110, the second micro LED 120, and the third micro LED 130 transferred to the second carrier substrate 450 may have the light emitting surface 112 (see FIG. 12) attached to an adhesive layer 470 (see FIG. 12) of the second carrier substrate 450.

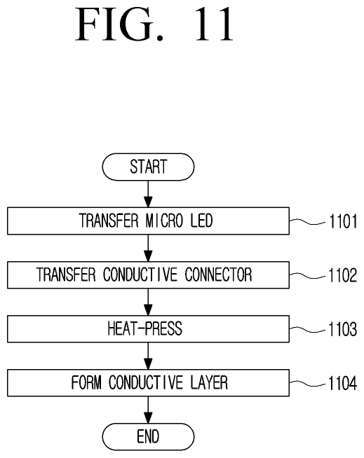

FIG. 11 is a flowchart for describing a method of manufacturing a display module 30 according to an embodiment of the disclosure. FIGS. 12, 13, 14, 15, 16, and 17 are diagrams describing a method of manufacturing a display module according to an embodiment.

The second carrier substrate 450 may be disposed on an upper side of the substrate 50. The second carrier substrate 450 and/or the substrate 50 may be moved to align the first micro LED 110, the second micro LED 120, and the third micro LED 130 of the second carrier substrate 450 to correspond to the first pad 51, the second pad 52, and the third pad 53 of the substrate 50.

Referring to FIG. 12, a laser beam L may be irradiated onto the second carrier substrate 450 to transfer the first micro LED 110, the second micro LED 120, and the third micro LED 130 arranged on the second carrier substrate 450 to the substrate 50 (e.g., operation 1101 of FIG. 11).

The method of transferring the first micro LED 110, the second micro LED 120, and the third micro LED 130 onto the substrate 50 is not limited to the laser transfer method, and a pick and place method, a transfer printing method, a roll-to-roll transfer method, and an electrostatic transfer method may be applied. The pick and place transfer method may be a method of picking up individual micro LEDs using a mechanical arm (e.g., robot arm) or a vacuum suction device and transferring the micro LEDs to a desired location. When the pick and place transfer method is used, the first micro LED 110, the second micro LED 120, and the third micro LED 130 may be transferred from the first carrier substrate 400 to the substrate 50 without going through the second carrier substrate 450. The transfer printing method may be a method of transferring all or the plurality of micro LEDs at once using the substrate on which the micro LEDs are arranged, and a flexible medium such as a silicone rubber pad or a polymer film is used to separate the micro LEDs from the carrier substrate and then transfer the micro LEDs to the substrate. The roll-to-roll transfer method may be a method of transferring micro LEDs to a substrate 50 by rolling and unrolling a flexible carrier substrate into a roll shape through a roller. The electric field transfer method may be a method of picking up micro LEDs by controlling the strength of an electric field and transferring the micro LEDs to the substrate 50.

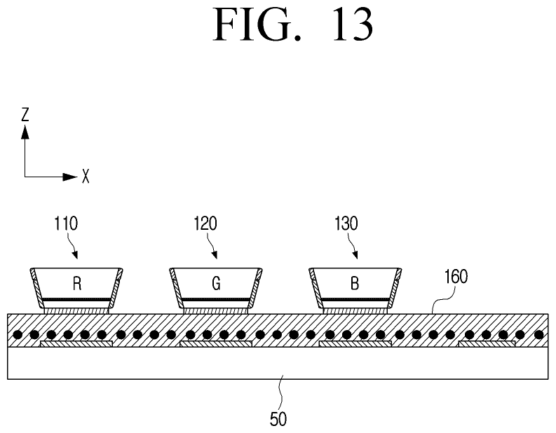

Referring to FIG. 13, the first micro LED 110, the second micro LED 120, and the third micro LED 130 may be separated from the second carrier substrate 450 and attached to the adhesive layer 160 of the substrate 50. The adhesive layer 160 may include, for example, an anisotropic conductive film (ACF) or an anisotropic conductive paste. The adhesive layer 160 may include the non-conductive resin layer 161 (e.g., a polymer-based adhesive) having adhesiveness and the plurality of conductive balls 163 (e.g., fine conductive balls) uniformly arranged within the non-conductive resin layer 161.

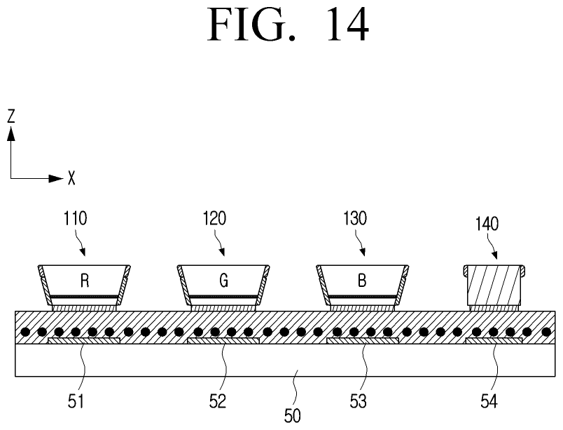

Referring to FIG. 14, when the plurality of micro LEDs are transferred to defined positions (e.g., positions corresponding to the first pad 51, the second pad 52, and the third pad 53) of the substrate 50, the conductive connector 140 may be transferred to defined positions (e.g., positions corresponding to the common electrode pads 54) of the substrate 50 (e.g., operation 1102 of FIG. 11).

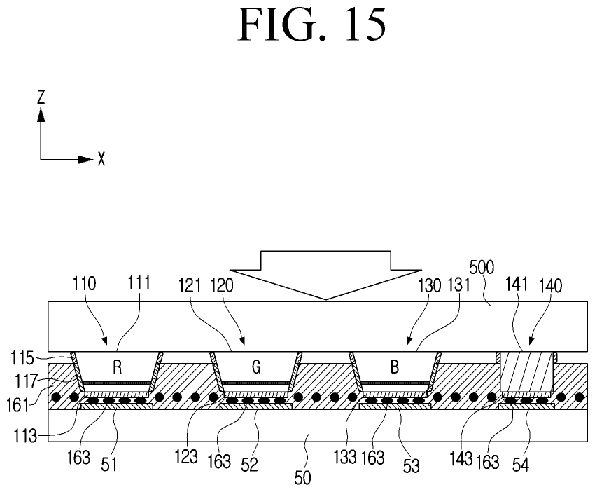

Referring to FIG. 15, the first micro LED 110, the second micro LED 120, and the third micro LED 130 and the conductive connector 140 may be heat-pressed toward the substrate 50 by a pusher 500 (operation 1103 of FIG. 11). In this case, the substrate 50 may be heated by a heater built into a stage supporting the substrate 50 and/or a heater built into the pusher 500. As the substrate 50 is heated, the non-conductive resin layer 161 of the adhesive layer 160 may be transformed into a liquid or jelly form. The first micro LED 110, the second micro LED 120, the third micro LED 130, and the conductive connector 140 may be drawn into the non-conductive resin layer 161 by the pressure of the pusher 500.

The first micro LED 110, the second micro LED 120, and the third micro LED 130 may be electrically connected to the first pad 51, the second pad 52, and the third pad 53 of the substrate 50 by at least one conductive ball 163. The conductive connector 140 may be electrically connected to the common electrode pads 54 of the substrate 50 by at least one conductive ball 163. The first micro LED 110, the second micro LED 120, the third micro LED 130, and the conductive connector 140 may be physically firmly fixed to the substrate 50 as the non-conductive resin layer 161 is cured.

The top surface of the non-conductive resin layer 161 may be located at a height approximately corresponding to the top of the reflective layer 117. In this case, the second electrodes 115, 125, and 135 of the first micro LED 110, the second micro LED 120, and the third micro LED 130 may be exposed without being covered by the non-conductive resin layer 161.

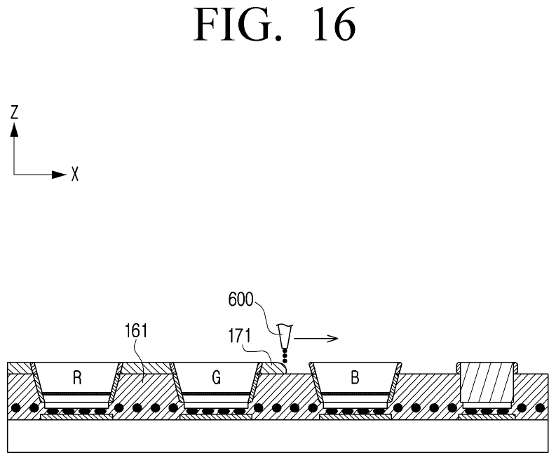

Referring to FIG. 16, a low-viscosity liquid ink 171 containing a conductive member (e.g., conductive particles) may be applied to the top surface of the adhesive layer 160 through a nozzle 600. The low-viscosity liquid ink 171 may fill a space between the first micro LED 110, the second micro LED 120, the third micro LED 130, and the conductive connector 140 protruding from the top surface of the non-conductive resin layer 161.

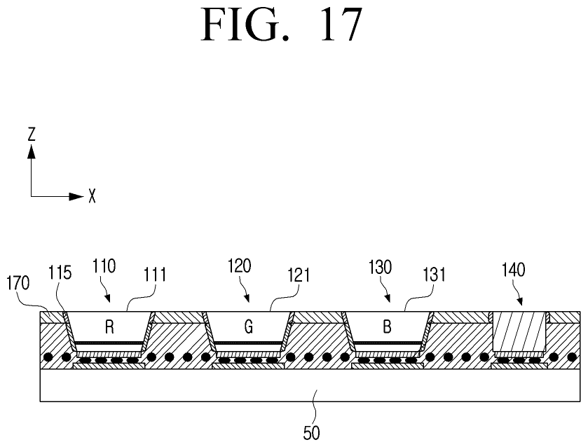

Referring to FIG. 17, the low viscosity liquid ink 171 may be cured to form the conductive layer 170 (operation 1104 of FIG. 11). The conductive layer 170 may be electrically connected to the second electrodes 115, 125, and 135 of the first micro LED 110, the second micro LED 120, and the third micro LED 130 and the fourth electrode 145 of the conductive connector 140, respectively.

The light emitting surfaces 111, 121, and 131 of the first micro LED 110, the second micro LED 120, and the third micro LED 130 may be completely exposed without being covered by the conductive layer 170. When a transparent electrode is formed on the light emitting surface of the micro LED, the light transmittance of the transparent electrode may be low, resulting in a loss of brightness, and power consumption may be increased to compensate for the loss of brightness. According to an embodiment of the disclosure, the micro LED may improve the reduction in brightness due to the transparent electrode since the light emitting surface is completely exposed without being covered by the transparent electrode or the like, and may improve the power consumption because there is no need to increase the power to compensate for the reduction in brightness.

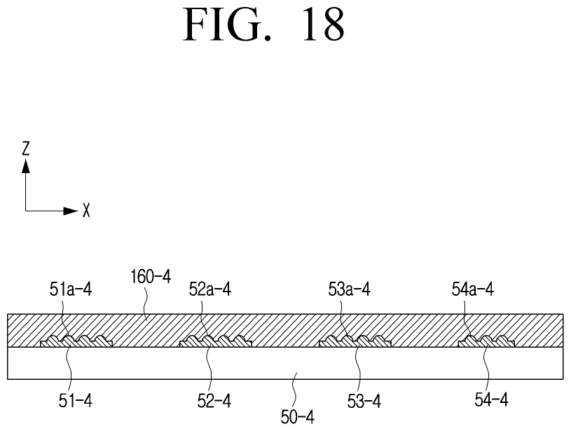

The connection between the first electrodes 113, 123, and 133 of the first micro LED 110, the second micro LED 120, and the third micro LED 130 and the first pads 51, 52, and 54 of the substrate 50, and the connection between the third electrode 143 of the conductive connector 140 and the common electrode pad 54 of the substrate 50 may be made by an anisotropic conductive film or anisotropic conductive paste, but is not limited thereto, and may be made by the embodiments described with reference to FIGS. 18 to 23 below.

FIGS. 18, 19, and 20 are diagrams describing a method of manufacturing a display module 30 according to an embodiment of the disclosure.

Referring to FIG. 18, three first pads 51-4, 52-4, and 53-4 and a common electrode pad 54-4 may be provided on the substrate 50-4. The three first pads 51-4, 52-4, and 53-4 and one common electrode pad 54-4 may be configured to correspond to one pixel. The substrate 50 may include a plurality of sets of the first pads 51-4, 52-4, and 53-4 and a plurality of common electrode pads 54-4 corresponding to the plurality of pixels.

An adhesive layer 160-4 covering the first pads 51-4, 52-4, and 53-4 and the common electrode pad 54-4 may be applied to the top surface of the substrate 50-4. The adhesive layer 160-4 may be a non-conductive film (NCF). The adhesive layer 160-4 may have a black or a black-based color to absorb external light and improve the mixing of lights emitted from the first micro LED 110-4, the second micro LED 120-4, and the third micro LED 130-4.

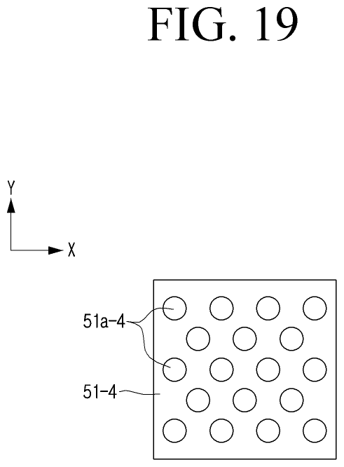

Referring to FIG. 19, the first pad 51-4 may have a plurality of contact protrusions 51a-4 provided on the top surface. The plurality of contact protrusions 51a-4 may be formed integrally with the first pad 51-4 and may have elasticity. The plurality of contact protrusions 51a-4 may protrude from the top surface of the first pad 51-4 by a constant height (e.g., about 1 to 3 μm). The plurality of contact protrusions 51a-4 may be uniformly arranged on the top surface of the first pad 51-4 at a constant interval from each other. The remaining first pads 52-4 and 53-4 and the common electrode pad 54-4 may include a plurality of contact protrusions 52a-4, 53a-4, and 54a-4 similar to the first pad 51-4, respectively.

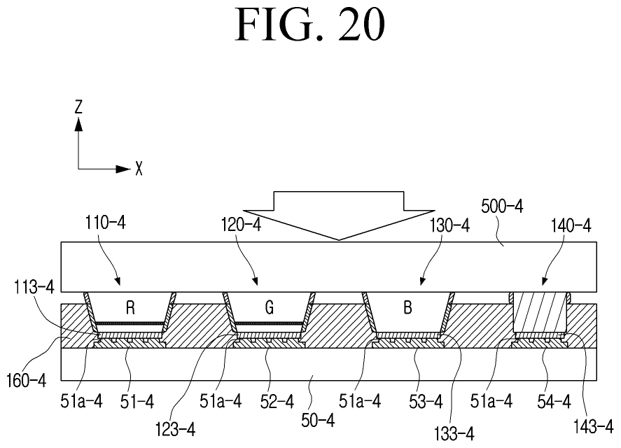

Referring to FIG. 20, the first micro LED 110-4, the second micro LED 120-4, the third micro LED 130-4, and the conductive connector 140-4 transferred onto the adhesive layer 160-4 of the substrate 50-4 may be heat-pressed. The first micro LED 110-4, the second micro LED 120-4, the third micro LED 130-4, and the conductive connector 140-4 may be introduced into the adhesive layer 160-4 while being pressed toward the substrate 50-4 by the pusher 500-4.

A plurality of contact protrusions 51a-4, 52a-4, and 53a-4 of the first pads 51-4, 52-4, and 53-4 may contact the first electrodes 113-4, 123-4, and 133-4 of the first micro LED 110-4, the second micro LED 120-4, and the third micro LED 130-4. The plurality of contact protrusions 54a-4 of the common electrode pad 54-4 may contact the third electrode 143-4 of the conductive connector 143-4.

In this case, the contact area of the plurality of contact protrusions 51a-4, 52a-4, and 53a-4 of the first pad 51-4, 52-4, and 53-4 with the first electrodes 113-4, 123-4, and 133-4 of the first micro LED 110-4, the second micro LED 120-4, and the third micro LED 130-4 may increase as they are deformed by the pressure. The connectivity may be improved as the plurality of contact protrusions 51a-4, 52a-4, and 53a-4 of the first pad 51-4, 52-4, and 53-4 are in close contact with the first electrodes 113-4, 123-4, and 133-4 of the first micro LED 110-4, the second micro LED 120-4, and the third micro LED 130-4 by the elasticity.

The contact area of the plurality of contact protrusions 54a-4 of the common electrode pad 54-4 with the third electrode 143-4 of the conductive connector 143-4 may increase as they are deformed by the pressure. The plurality of contact protrusions 54a-4 of the common electrode pad 54-4 may improve the connectivity as they are in close contact with the third electrode 143 of the conductive connector 140-4 due to the elasticity.

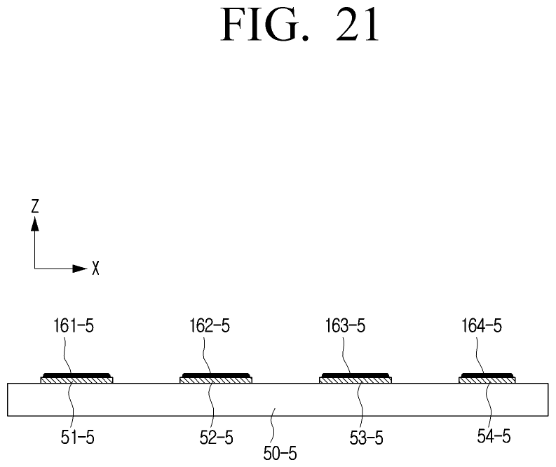

FIGS. 21, 22, and 23 are diagrams describing a method of manufacturing a display module 30 according to an embodiment of the disclosure.

Referring to FIG. 21, the first pads 51-5, 52-5, and 53-5 of the substrate 50-5 and the common electrode pad 54-5 may have solder 161-5, 162-5, 163-5, and 164-5 applied to their top surfaces, respectively. The solders 161-5, 162-5, 163-5, and 164-5 may also be applied to the first electrode 113-5, 123-5, and 133-5 of the first micro LED 110-5, the second micro LED 120-5, and the third micro LED 130-5 and the third electrode 143-5 of the conductive connector 140-5.

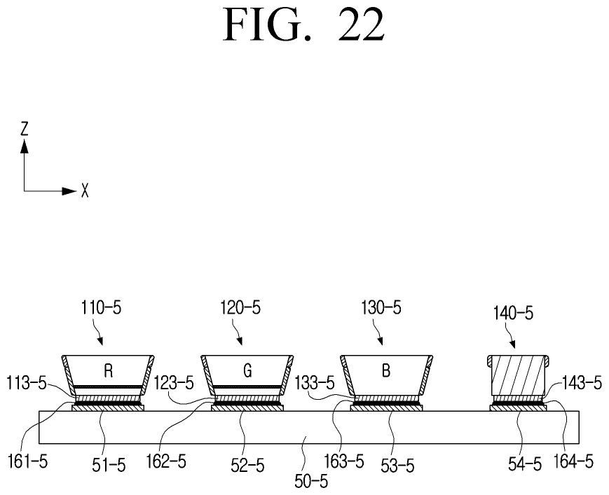

Referring to FIG. 22, the first micro LED 110-5, the second micro LED 120-5, the third micro LED 130-5, and the conductive connector 140-5 may be transferred to the substrate 50-5. In this case, the first electrodes 113-5, 123-5, and 133-5 of the first micro LED 110-5, the second micro LED 120-5, and the third micro LED 130-5 may contact the solders 161-5, 162-5, and 163-5 on the first pads 51-5, 52-5, and 53-5 of the substrate 50-5. The third electrode 143-5 of the conductive connector 140-5 may contact the solder 143-5 on the common electrode pads 54-5 of the substrate 50-5.

When the reflow process is performed, the first micro LED 110-5, the second micro LED 120-5, and the third micro LED 130-5 may be physically and electrically connected to the first pad 51-5, 52-5, and 53-5 of the substrate 50-5 through the solders 161-5, 162-5, and 163-5. The third electrode 143-5 of the conductive connector 140-5 may be physically and electrically connected to the common electrode pad 54-5 of the substrate 50-5 by the solder 143-5.

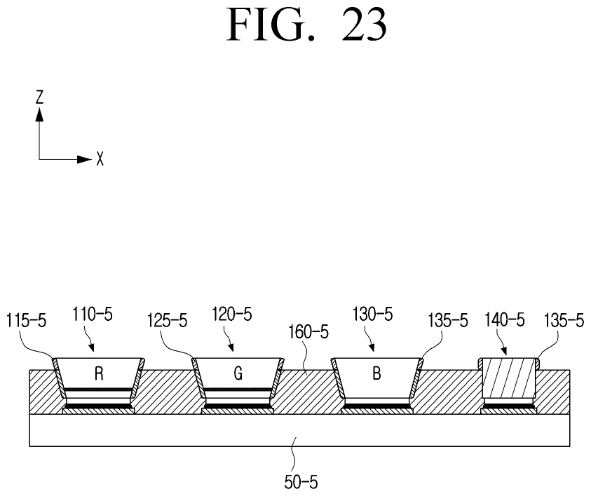

Referring to FIG. 23, an insulating layer 160-5 may be applied on the substrate 50-5. In this case, the insulating layer 160-5 may be filled between the first micro LED 110-5, the second micro LED 120-5, the third micro LED 130-5, and the conductive connector 140-5. The insulating layer 160-5 may be formed to a height that does not cover the second electrodes 115-5, 125-5, and 135-5 of the first micro LED 110-5, the second micro LED 120-5, and the third micro LED 130-5, and the fourth electrode 145-5 of the conductive connector 140-5. The insulating layer 160-5 may have a black or black-based color to absorb external light and improve the mixing of lights emitted from the first micro LED 110-5, the second micro LED 120-5, and the third micro LED 130-5. The insulating layer 160-5 may be an NCF having adhesive properties.

The second electrodes 115-5, 125-5, and 135-5 of the first micro LED 110-5, the second micro LED 120-5, and the third micro LED 130-5, and the fourth electrode 145-5 of the conductive connector 140-5 may be firmly fixed on the substrate 50-5 as the insulating layer 160-5 is cured. The second electrodes 115-5, 125-5, and 135-5 of the first micro LED 110-5, the second micro LED 120-5, and the third micro LED 130-5 and the fourth electrode 145-5 of the conductive connector 140-5 may be electrically connected to the common electrode pad 54-5 of the substrate 50-5 by the conductive layer 170 (see FIG. 3) formed on the insulating layer 160-5.

According to an embodiment of the disclosure, the connection between the second electrodes 115-5, 125-5, and 135-5 of the first micro LED 110-5, the second micro LED 120-5, and the third micro LED 130-5 and the first pad 51-5, 52-5, and 53-5 of the substrate 50-5 and the connection between the fourth electrode 145-5 of the conductive connector 140-5 and the common electrode pad 54-5 may be made by nanocarbon connection.

The nanocarbon connection may be implemented by using nanoscale carbon-based materials (e.g., carbon nanotubes (CNTs), graphene) to connect between the second electrodes 115-5, 125-5, and 135-5 of the first micro LED 110-5, the second micro LED 120-5, and the third micro LED 130-5 and the first pads 51-5, 52-5, and 53-5 of the substrate 50-5, and connect between the fourth electrode 145-5 of the conductive connector 140-5 and the common electrode pad 54-5.

The nanocarbon material may be produced in the form of ink and applied to the top surfaces of the first pads 51-5, 52-5, and 53-5 of the substrate 50-5 and the common electrode pad 54-5 by screen printing, inkjet printing, or dipping.

The nanocarbon material applied to the top surface of each of the first pads 51-5, 52-5, and 53-5 and the common electrode pad 54-5 may be aligned in a specific direction using an electric or magnetic field to strengthen the electrical connection between the second electrodes 115-5, 125-5, and 135-5 of the first micro LED 110-5, the second micro LED 120-5, and the third micro LED 130-5 and the first pad 51-5, 52-5, and 53-5 of the substrate 50-5 and the electrical connection between the fourth electrode 145-5 of the conductive connector 140-5 and the common electrode pad 54-5.

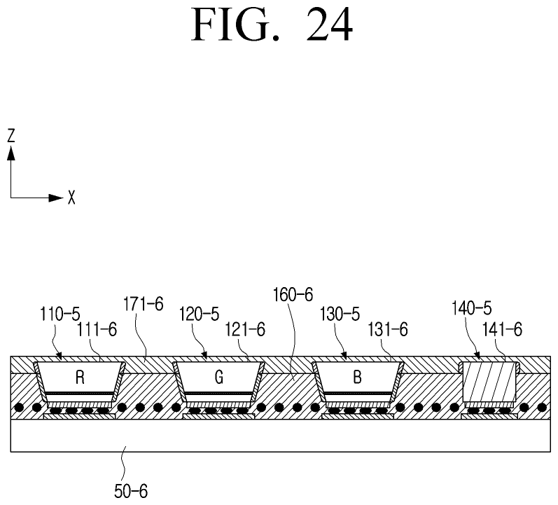

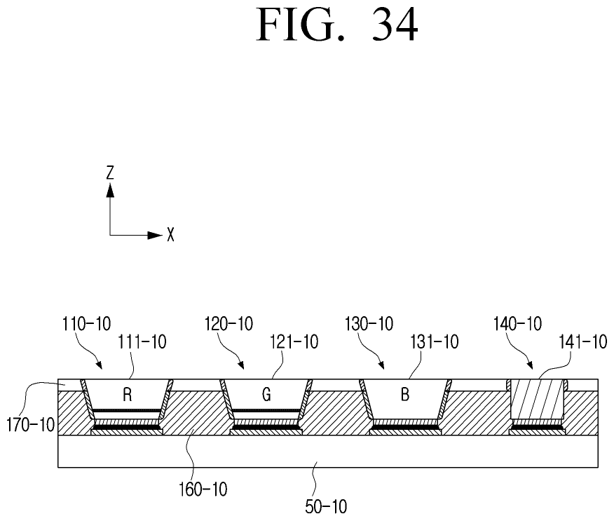

The conductive layer 170 connecting the second electrodes 115, 125, and 125 of the first micro LED 110, the second micro LED 120, and the third micro LED 130 and the fourth electrode 145 of the conductive connector 140 may be formed using the conductive low-viscosity liquid ink 171, but is not limited thereto, and may be formed by the embodiments described below with reference to FIGS. 24 to 37.

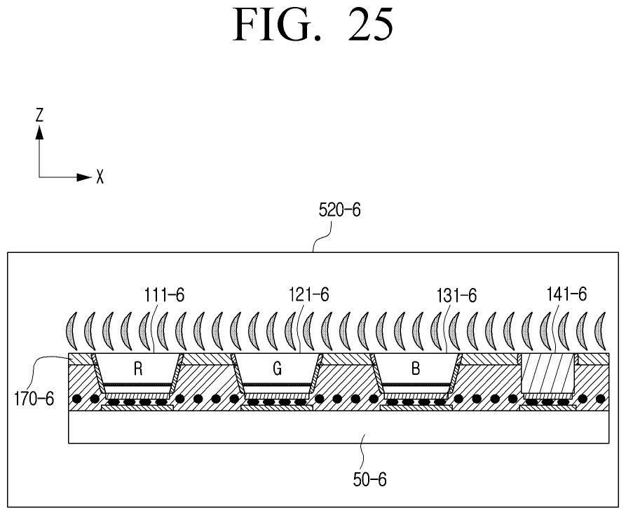

FIGS. 24 and 25 are diagrams describing a method of manufacturing a display module 30 according to an embodiment of the disclosure.

According to an embodiment of the disclosure, a conductive member (e.g., a conductive paste 171-6 applied on a substrate 50-6) may be formed into a conductive layer 170-6 by plasma etching.

Referring to FIG. 24, the top surface of the adhesive layer 160-6 and the top surface of the first micro LED 110-6, the second micro LED 120-6, the third micro LED 130-6, and the conductive connector 140-6 may be coated with the conductive paste 171-6. In this case, the light emitting surfaces 111-6, 121-6, and 131-6 of the first micro LED 110-6, the second micro LED 120-6, and the third micro LED 130-6 and the top surface 141-6 of the conductive connector 140-6 may be covered by the conductive paste 171-6. The conductive paste 171-6 may also be replaced with a conductive film.

Referring to FIG. 25, the conductive paste 171-6 may be cured and then the substrate 50-6 may be placed in a vacuum chamber 520-6. After a reactive gas (e.g., CF4, SF6, O2) is injected into the vacuum chamber 520-6, a high-frequency current may be used to make the gas into a plasma state. The plasma generated in the vacuum chamber 520-6 may be composed of ionized particles. These particles may collide with the top surface of the conductive paste 171-6. Accordingly, a reaction occurs according to the chemical composition of the conductive paste 171-6, and the particles react chemically and are converted into volatile compounds, which may then be removed by a vacuum pump.

Since the plasma etching enables vertical and accurate etching using a directional ion beam, a portion of the conductive paste 171-6 may be removed vertically downward from the top surface of the conductive paste 171-6 by a certain thickness. The top portion of the conductive paste 171-6 corresponding to the depth corresponding to the light emitting surface 111-6, 121-6, and 131-6 of the first micro LED 110-6, the second micro LED 120-6, and the third micro LED 130-6 among the entire thickness of the conductive paste 171-6 may be removed.

By the plasma etching, the light emitting surface 111-6, 121-6, and 131-6 of the first micro LED 110-6, the second micro LED 120-6, and the third micro LED 130-6 may be completely exposed. In this case, the top surface 141-6 of the conductive connector 140-6 may also be exposed. In this way, the conductive paste 171-6 may be formed into the conductive layer 170-6 by the plasma etching.

Even when the conductive paste 171-6 covering the top surface 141-6 of the conductive connector 140-6 is not removed by the plasma etching, it may not affect the brightness of the first micro LED 110-6, the second micro LED 120-6, and the third micro LED 130-6.

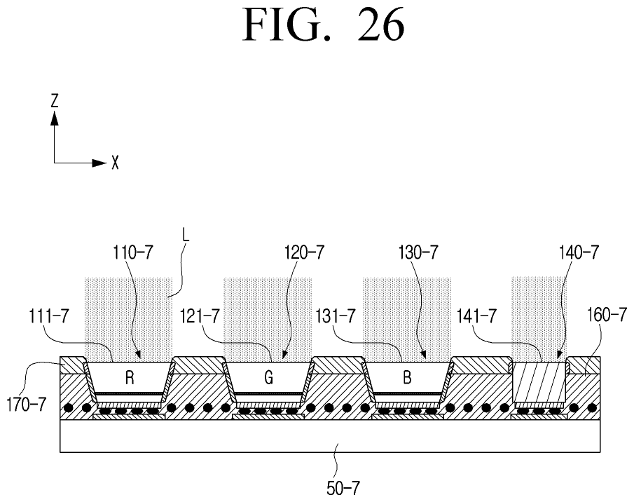

FIG. 26 is a diagram describing a method of manufacturing a display module 30 according to an embodiment of the disclosure.

According to an embodiment of the disclosure, the conductive paste (or conductive film) applied on the substrate 50-7 may be formed into a conductive layer 170-7 by the laser etching.

The top surface of the adhesive layer 160-7 and the light emitting surfaces 111-7, 121-7, and 131-7 of the first micro LED 110-7, the second micro LED 120-7, and the third micro LED 130-7, and the top surface 141-7 of the conductive connector 140-7, may be coated with a conductive paste (or a conductive film).

Referring to FIG. 26, a laser beam L may be irradiated onto the conductive paste (or the conductive film) covering the light emitting surfaces 111-7, 121-7, and 131-7 of the first micro LED 110-7, the second micro LED 120-7, and the third micro LED 130-7 and the top surface 141-7 of the conductive connector 140-7. Accordingly, the conductive paste (or the conductive film) covering the light emitting surfaces 111-7, 121-7, and 131-7 of the first micro LED 110-7, the second micro LED 120-7, and the third micro LED 130-7 and the top surface 141-7 of the conductive connector 140-7 may be removed.

Even when the conductive paste (or the conductive film) covering the top surface 141-7 of the conductive connector 140-7 is not removed by the laser beam, it may not affect the brightness of the first micro LED 110-7, the second micro LED 120-7, and the third micro LED 130-7. Therefore, only the conductive paste (or conductive film) covering the light emitting surfaces 111-7, 121-7, and 131-7 of the first micro LED 110-7, the second micro LED 120-7, and the third micro LED 130-7 may be removed by the laser beam.

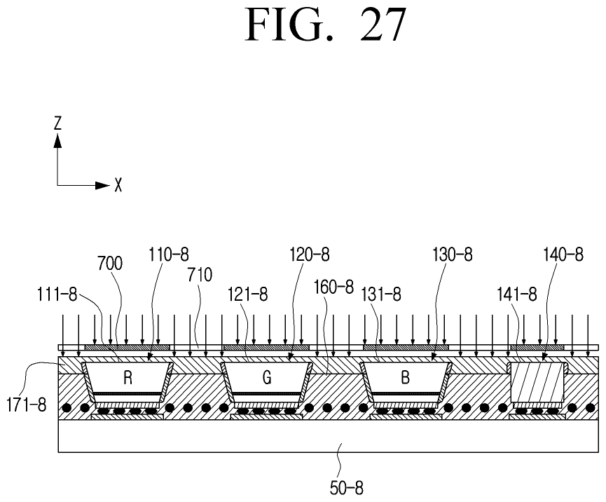

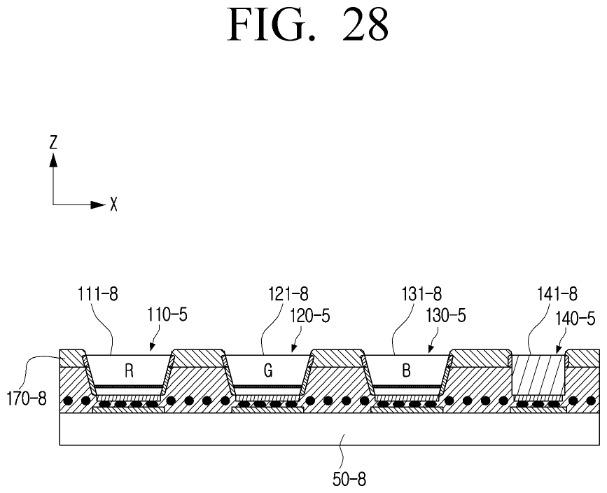

FIGS. 27 and 28 are diagrams illustrating a method of manufacturing a display module 30 according to an embodiment of the disclosure. According to an embodiment of the disclosure, a photosensitive conductive ink 171-8 applied on the substrate 50-8 may be formed into the conductive layer 170-8 through photolithography.

Referring to FIG. 27, the top surface of the adhesive layer 160-8 and the light emitting surfaces 111-8, 121-8, and 131-8 of the first micro LED 110-8, the second micro LED 120-8, and the third micro LED 130-8, and the top surface 141-8 of the conductive connector 140-8, may be coated with a photosensitive conductive ink 171-8. After coating, the photosensitive conductive ink 171-8 may be heated to evaporate the solvent, and the viscosity of the photosensitive conductive ink 171-8 may be increased to be semi-cured at a constant temperature (e.g., about 90 to 100° C.) for a constant time so that it may be attached to the substrate 50-8.

As a pretreatment step for removing a portion of the photosensitive conductive ink 171-8 that is semi-cured, a mask 700 having a plurality of openings 710 through which ultraviolet rays pass may be placed on the upper side of the photosensitive conductive ink 171-8. In this case, the plurality of openings 710 of the mask 700 may be arranged to correspond to areas to be used as the conductive layer 170-8 among the entire area of the photosensitive conductive ink 171-8. The light emitting surfaces 111-8, 121-8, and 131-8 of the first micro LED 110-8, the second micro LED 120-8, and the third micro LED 130-8 and the top surface 141-8 of the conductive connector 140-8 may be covered by the mask 700.

The pattern may be transferred to the photosensitive conductive ink 171-8 by irradiating the substrate 50-8 with ultraviolet light through the mask 700. The photosensitive conductive ink 171-8 exposed to the ultraviolet light may be chemically changed. In this case, the photosensitive conductive ink 171-8 may correspond to a negative photoresist.

Referring to FIG. 28, portions of the photosensitive conductive ink 171-8 that have not been exposed to ultraviolet rays may be removed by a developer. The portions of the photosensitive conductive ink 171-8 that cover the light emitting surfaces 111-8, 121-8, and 131-8 of the first micro LED 110-8, the second micro LED 120-8, and the third micro LED 130-8 and the top surface 141-8 of the conductive connector 140-8 may be removed by the developer.

The photosensitive conductive ink 171-8 remaining on the substrate 50-8 may function as the conductive layer 170-8. The height of the conductive layer 170-8 may be slightly higher than the light emitting surfaces 111-8, 121-8, and 131-8 of the first micro LED 110-8, the second micro LED 120-8, and the third micro LED 130-8. Due to the height difference between the light emitting surfaces 111-8, 121-8, and 131-8 of the conductive layer 170-8 and the first micro LED 110-8, the second micro LED 120-8, and the third micro LED 130-8, the conductive layer 170-8 may improve the mixing of the lights emitted from the first micro LED 110-8, the second micro LED 120-8, and the third micro LED 130-8.

Even when the portions of the photosensitive conductive ink 171-8 covering the top surface 141-8 of the conductive connector 140-8 are not removed, it may not affect the brightness of the first micro LED 110-8, the second micro LED 120-8, and the third micro LED 130-8. Therefore, only the portions of the photosensitive conductive ink 171-8 covering the light emitting surfaces 111-8, 121-8, and 131-8 of the first micro LED 110-8, the second micro LED 120-8, and the third micro LED 130-8 may be removed.

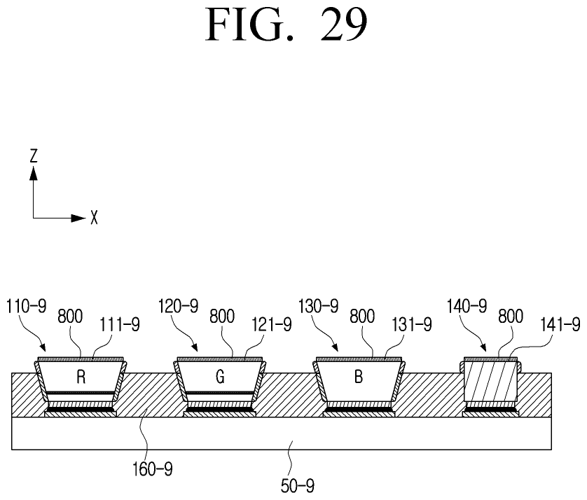

FIGS. 29, 30, and 31 are diagrams illustrating a method of manufacturing a display module 30 according to an embodiment of the disclosure.

According to an embodiment of the disclosure, the photosensitive conductive ink 171-9 applied on the substrate 50-9 may be formed into a conductive layer 170-9 through photolithography. Referring to FIG. 29, the light emitting surfaces 111-9, 121-9, and 131-9 of the first micro LED 110-9, the second micro LED 120-9, and the third micro LED 130-9 and the top surface 141-9 of the conductive connector 140-9 may be patterned to be covered with photoresist 800.

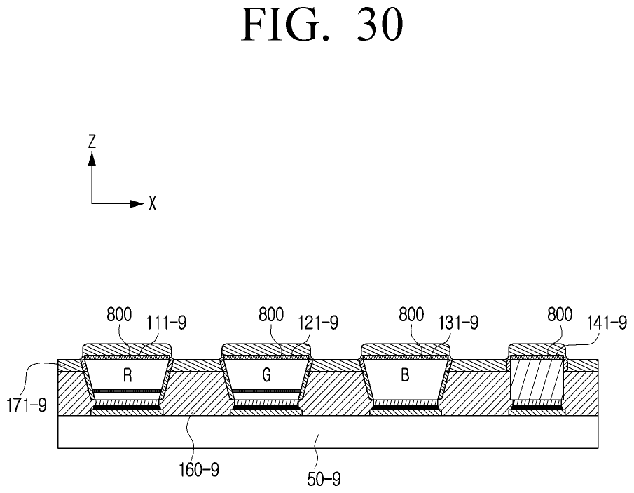

Referring to FIG. 30, the top surface of the adhesive layer 160-9 and the photoresist 800 may be coated with photosensitive conductive ink 171-9. After coating, the photosensitive conductive ink 171-9 may be semi-cured before exposure.

As a pretreatment step for removing a portion of the photosensitive conductive ink 171-9 that is semi cured, the mask 700 (see FIG. 27) having a plurality of openings 710 (see FIG. 27) through which ultraviolet rays pass may be disposed on the upper side of the photosensitive conductive ink 171-9. The light emitting surfaces 111-9, 121-9, and 131-9 of the first micro LED 110-9, the second micro LED 120-9, and the third micro LED 130-9 and the top surface 141-9 of the conductive connector 140-9 may be covered by the mask 700.

The ultraviolet light may be irradiated to the substrate 50-9 through the mask 700 to transfer a pattern to the photosensitive conductive ink 171-9. A portion of the photosensitive conductive ink 171-9 exposed to the ultraviolet light may be chemically changed. In this case, the conductive ink 171-9 may correspond to the negative photoresist. The first development may be performed to remove the portion of the photosensitive conductive ink 171-9 exposed to the ultraviolet light with the first developer. For example, the portion of the photosensitive conductive ink 171-9 may be removed by the plasma etching or laser etching.

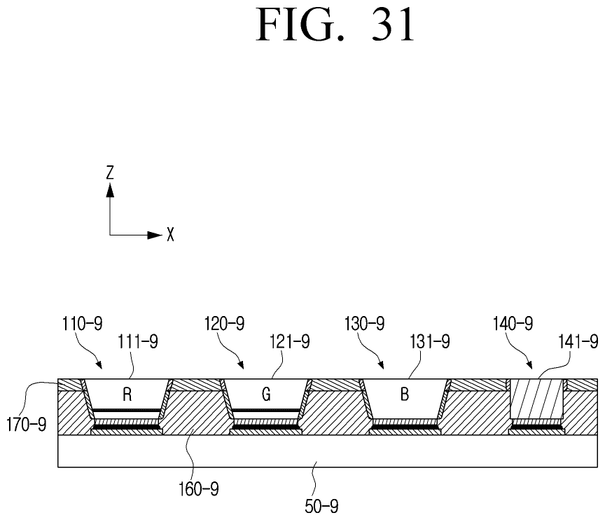

Referring to FIG. 31, a second development may be performed to remove the photoresist 800 using a second developer. The portion of the photosensitive conductive ink 171-9 that is not removed from the photoresist 800 in the first development may remain. This portion of the photosensitive conductive ink 171-9 may be removed together with the photoresist 800 in the second development. Accordingly, the light emitting surfaces 111-9, 121-9, and 131-9 of the first micro LED 110-9, the second micro LED 120-9, and the third micro LED 130-9 may be completely exposed. Even when the photosensitive conductive ink 171-9 or the photoresist 800 covering the top surface 141-9 of the conductive connector 140-9 is not removed, the brightness of the first micro LED 110-9, the second micro LED 120-9, and the third micro LED 130-9 may not be affected. Therefore, only the portion of the photosensitive conductive ink 171-9 and the photoresist 800 covering the light emitting surfaces 111-9, 121-9, and 131-9 of the first micro LED 110-9, the second micro LED 120-9, and the third micro LED 130-9 may be removed.

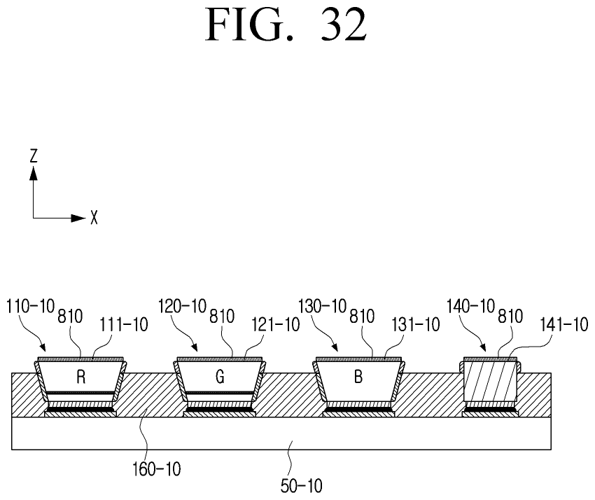

FIGS. 32, 33, and 34 are diagrams illustrating a method of manufacturing a display module 30 according to an embodiment of the disclosure.

According to an embodiment of the disclosure, a transparent electrode material (e.g., ITO, Indium Zinc Gallium Oxide (IZGO)) deposited on a substrate 50-10 may be formed into a conductive layer 170-10 through plasma etching.

Referring to FIG. 32, the light emitting surfaces 111-10, 121-10, and 131-10 of the first micro LED 110-10, the second micro LED 120-10, and the third micro LED 130-10 and the top surface 141-10 of the conductive connector 140-10 may be patterned to be covered with a photoresist 810.

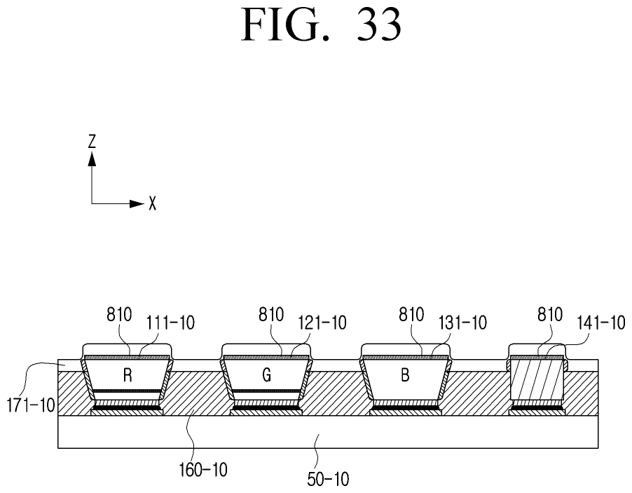

Referring to FIG. 33, the top surface of the adhesive layer 160-10 and the photoresist 810 may be coated with a transparent electrode material 171-10.

Referring to FIG. 31, the transparent electrode material 171-10 covering the photoresist 810 may be removed by the plasma etching. For example, the transparent electrode material 171-10 may also be removed by the laser etching.

A development process may be performed to remove the photoresist 810 covering the light emitting surfaces 111-10, 121-10, and 131-10 of the first micro LED 110-10, the second micro LED 120-10, and the third micro LED 130-10 using a developer. Accordingly, the light emitting surfaces 111-10, 121-10, and 131-10 of the first micro LED 110-10, the second micro LED 120-10, and the third micro LED 130-10 may be completely exposed.

Even when the transparent electrode material 171-10 or the photoresist 810 covering the top surface 141-10 of the conductive connector 140-10 is not removed, the brightness of the first micro LED 110-10, the second micro LED 120-10, and the third micro LED 130-10 may not be affected. Therefore, only the portion of the transparent electrode material 171-10 and the photoresist 810 covering the light emitting surfaces 111-10, 121-10, and 131-10 of the first micro LED 110-10, the second micro LED 120-10, and the third micro LED 130-10 may be removed.

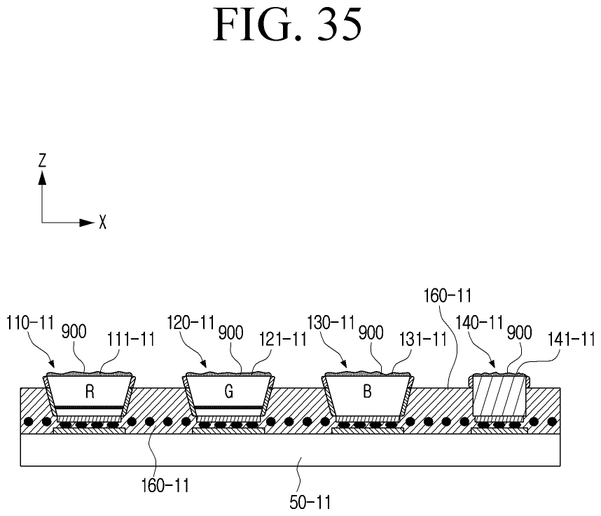

FIGS. 35, 36, and 37 are diagrams illustrating a method of manufacturing a display module 30 according to an embodiment of the disclosure.

Referring to FIG. 35, the first micro LED 110-11, the second micro LED 120-11, and the third micro LED 130-11, which are separated from the second carrier substrate 450 (see FIG. 12) and laser-transferred to the substrate 50-11, may have residue 900, which is part of an adhesive layer (e.g., the adhesive layer 470, see FIG. 12), remaining on the light emitting surfaces 111-11, 121-11, and 131-11. According to an embodiment of the disclosure, the residue 900 may be utilized as a pattern such as the photoresists 800 and 810 (see FIGS. 29 and 32). The residue 900 may be polyimide (PI).

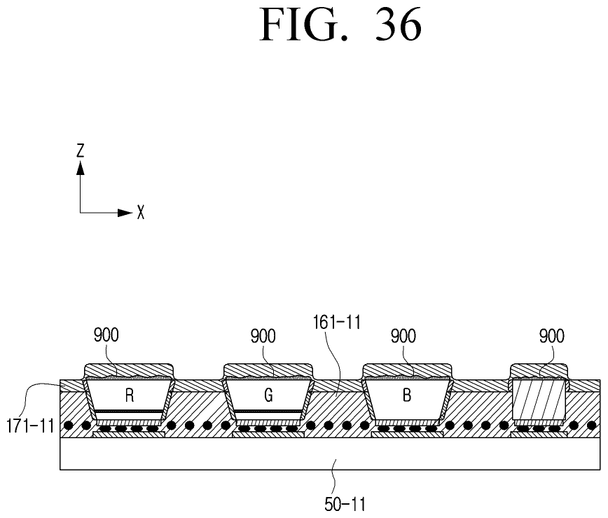

Referring to FIG. 36, the top surface of the adhesive layer 160-11 and the residue 900 may be coated with a transparent electrode material 171-11.

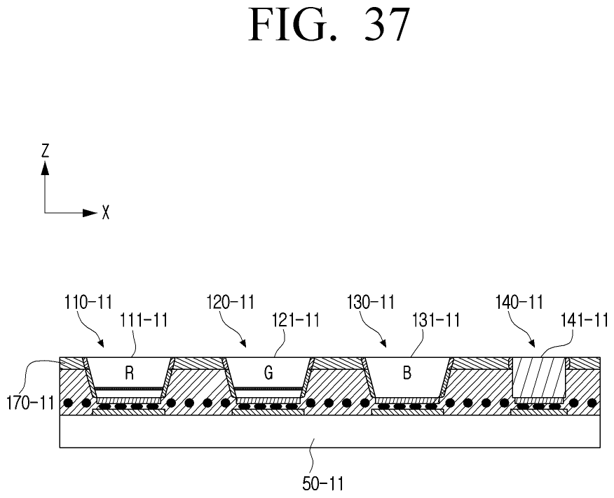

Referring to FIG. 37, the transparent electrode material 171-11 covering the residue 900 may be removed by the plasma etching. For example, the transparent electrode material 171-11 may also be removed by the laser etching.

The residue 900 covering the light emitting surfaces 111-11, 121-11, and 131-11 of the first micro LED 110-11, the second micro LED 120-11, and the third micro LED 130-11 may be removed through a descum process. The descum process may effectively decompose and remove polymer materials such as PI by using oxygen plasma. Accordingly, the light emitting surfaces 111-11, 121-11, and 131-11 of the first micro LED 110-11, the second micro LED 120-11, and the third micro LED 130-11 may be completely exposed.

Even when the portion of the transparent electrode material 171-11 or the residue 900 covering the top surface 141-11 of the conductive connector 140-11 is not removed, the brightness of the first micro LED 110-11, the second micro LED 120-11, and the third micro LED 130-11 may not be affected. Therefore, the portion of the transparent electrode material 171-11 and the residue 900 covering the light emitting surfaces 111-10, 121-10, and 131-10 of the first micro LED 110-11, the second micro LED 120-11, and the third micro LED 130-11 may be removed.

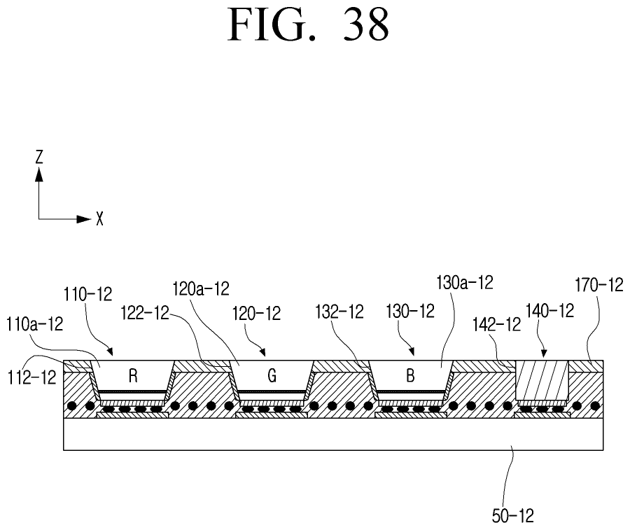

FIG. 38 is a cross-sectional view illustrating a pixel according to an embodiment of the disclosure.

Referring to FIG. 38, the first micro LED 110-11, the second micro LED 120-11, and the third micro LED 130-11 mounted on the substrate 50-12 may directly contact the conductive layer 170-12 with the side surfaces 112-12, 122-12, and 132-12 of the first micro LED 110-11, the second micro LED 120-11, and the third micro LED 130-11. In this case, the n-type semiconductor layers 110a-12, 120a-12, and 130a-12 of the first micro LED 110-11, the second micro LED 120-11, and the third micro LED 130-11 may be electrically connected to the conductive layer 170-2. Accordingly, the first micro LED 110-11, the second micro LED 120-11, and the third micro LED 130-11 may not include the second electrodes 115, 125, and 135, unlike the first micro LED 110, the second micro LED 120, and the third micro LED 130 illustrated in FIG. 3.

Since the first micro LED 110-11, the second micro LED 120-11, and the third micro LED 130-11 may be formed in operations that omit the step of forming the second electrode, the manufacturing process may be simplified to improve productivity and reduce manufacturing costs.

The conductive connector 140-12 may be electrically connected when the side surface 142-12 of the conductive connector 140-12 is in direct contact with the conductive layer 170-12. The conductive connector 140-12 may be formed of a material capable of minimizing electrical resistance (e.g., ohmic resistance) for the conductive layer 170-12.

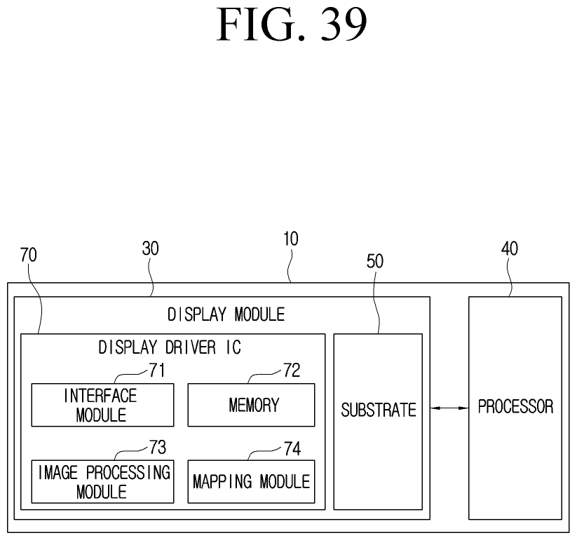

FIG. 39 is a block diagram illustrating a display device 10 according to an embodiment of the disclosure.

Referring to FIG. 39, the display device 10 may include the display module 30 and a processor 40. The display module 30 may include the substrate 50 and a display driver integrated circuit (IC) 70 for controlling driving of the plurality of micro light emitting diodes provided on the substrate 50.

The processor 40 may be implemented as a digital signal processor (DSP) for processing digital image signals, a microprocessor, a graphics processing unit (GPU), an artificial intelligence (AI) processor, a neural processing unit (NPU), or a time controller (TCON). The processor 40 is not limited thereto, and may include one or more from among a central processing unit (CPU), a micro controller unit (MCU), a micro processing unit (MPU), a controller, an application processor (AP), a communication processor (CP), and an ARM processor, or may be defined by the terms thereof. The processor 40 may be implemented as a system on chip (SoC) having a processing algorithm built into it, a large scale integration (LSI), or may be implemented in the form of an application specific integrated circuit (ASIC), or a field programmable gate array (FPGA).

The processor 40 may control hardware or software components connected to the processor 40 by driving an operating system or an application program, and may perform various data processing and calculations. In addition, the processor 40 may load commands or data received from at least one of the other components into a volatile memory and process them, and store various data in a nonvolatile memory.

The display driver IC 70 may include an interface module 71, a memory 72 (e.g., a buffer memory), an image processing module 73, and/or a mapping module 74. The display driver IC 70 may receive, for example, image data, or image information including image control signals corresponding to commands for controlling image data, from a corresponding component of the display device 10 through the interface module 71. For example, according to an embodiment, the image information may be received from the processor 40 (e.g., the main processor (e.g., the application processor) or the auxiliary processor (e.g., the graphic processing unit) that operates independently of the function of the main processor).

The display driver IC 70 may communicate with a sensor module (e.g., at least one sensor) through the interface module 71. In addition, the display driver IC 70 may store at least some of the received image information in the memory 72, for example, on a frame basis. The image processing module 73 may perform preprocessing or post-processing (e.g., resolution, brightness, or size adjustment) on at least some of the image data based on, for example, the characteristics of the image data or the characteristics of the substrate 50. The mapping module 74 may generate a voltage value or a current value corresponding to the image data preprocessed or post-processed through the image processing module 73. According to an embodiment, the generation of the voltage value or the current value may be performed based at least in part on, for example, the characteristics of the pixels of the substrate 50 (e.g., the arrangement of the pixels (RGB stripe or pentile structure), or the size of each of the sub-pixels). At least some pixels of the substrate 50 may be driven based at least in part on the voltage value or current value, for example, so that visual information (e.g., text, an image, or an icon) corresponding to the image data may be displayed through the substrate 50.

The display driver IC 70 may transmit a driving signal (e.g., a driver driving signal, a gate driving signal, etc.) to the display based on the image information received from the processor 40.

The display driver IC 70 may display an image based on the image signal received from the processor 40. For example, the display driver IC 70 may generate driving signals for a plurality of sub-pixels based on the image signal received from the processor 40, and may display an image by controlling the light emission of the plurality of sub-pixels based on the driving signals.

According to an embodiment of the disclosure, the display module 30 may further include a touch circuit. The touch circuit may include a touch sensor and a touch sensor IC for controlling the same. The touch sensor IC may control the touch sensor to detect, for example, a touch input or a hovering input for a specified position of the substrate 50. For example, the touch sensor IC may detect a touch input or hovering input by measuring a change in a signal (e.g., voltage, light, resistance, or charge) for a designated location on the substrate 50. The touch sensor IC may provide information (e.g., location, area, pressure, or time) about the detected touch input or hovering input to the processor 40. According to an embodiment, at least a portion of the touch circuit (e.g., the touch sensor IC) may be included as a part of the display driver IC 70, or the substrate 50, or as a part of another component (e.g., an auxiliary processor) disposed externally to the display module 30.

According to an embodiment of the disclosure, the pixel driving method of the display module 30 may be an active matrix (AM) driving method or a passive matrix (PM) driving method.

According to an embodiment of the disclosure, the display device 10 may include the display module 30. The display module 30 may display various images. Here, the images may include still images and/or moving images. The display module 30 may display various images such as broadcasting content, multimedia content, etc. In addition, the display module 30 may also display a user interface and icons.

According to an embodiment of the disclosure, the display device 10 may include a plurality of display modules 30 and a support substrate to which the plurality of display modules 30 are electrically connected, respectively. The display device 10 may be implemented as a large format display (LFD) in which a plurality of display modules 30 are arranged in a lattice on the support substrate.

Although example embodiments of the disclosure have been described above with reference to the accompanying drawings, the disclosure is not limited to the example embodiments, and embodiments of the disclosure may be variously modified by those skilled in the art to which the disclosure pertains without departing from the spirit and scope of the disclosure. These modifications should also be understood to fall within the spirit and scope of the disclosure.

What is claimed is:

1. A display module comprising:
a substrate comprising a first pad and a common electrode pad;
a light emitting diode comprising:
a first electrode connected to the first pad; and
a second electrode;
a conductive connector connected to the common electrode pad, and connecting the second electrode to the common electrode pad;
an adhesive layer on the substrate; and
a conductive layer on the adhesive layer, the conductive layer connecting the second electrode to the conductive connector,
wherein the second electrode of the light emitting diode is on a side surface of the light emitting diode, the side surface being between a light emitting surface of the light emitting diode and a bottom surface of the light emitting diode, the bottom surface being opposite to the light emitting surface, and
wherein the light emitting surface of the light emitting diode is exposed from the conductive layer, and the conductive layer surrounds the second electrode of the light emitting diode.

2. The display module according to claim 1, wherein a level of the light emitting surface of the light emitting diode is the same as a level of a top surface of the conductive layer.

3. The display module according to claim 1, wherein the second electrode of the light emitting diode is adjacent to the light emitting surface of the light emitting diode.

4. The display module according to claim 1, wherein the second electrode of the light emitting diode comprises a closed loop shape that surrounds the side surface of the light emitting diode.

5. The display module according to claim 1, wherein the second electrode of the light emitting diode comprises:
a first portion at a first corner of the side surface of the light emitting diode; and
a second portion at a second corner of the side surface of the light emitting diode, the second portion diagonally arranged with respect to the first corner, and
wherein the first portion and the second portion are symmetrical with respect to each other.

6. The display module according to claim 1, wherein the second electrode of the light emitting diode comprises:
a first portion on a first side surface of the light emitting diode; and
a second portion on a second side surface of the light emitting diode, the second side surface facing away from the first side surface, and
wherein the first portion and the second portion are symmetrical with respect to each other.

7. The display module according to claim 1, wherein the adhesive layer comprises an anisotropic conductive film comprising a black color.

8. The display module according to claim 1, wherein the adhesive layer comprises a non-conductive film comprising a black color,
wherein the display module further comprises a third electrode on a bottom surface of the conductive connector,
wherein the first pad of the substrate comprises a plurality of first contact protrusions that protrude from a top surface of the first pad, and the plurality of first contact protrusions elastically contact the first electrode of the light emitting diode, and
wherein the common electrode pad of the substrate comprises a plurality of second contact protrusions that protrude from a top surface of the common electrode pad, and the plurality of second contact protrusions elastically contact the third electrode.

9. The display module according to claim 1, wherein the first electrode of the light emitting diode and the first pad of the substrate are connected by a first solder,
wherein the display module further comprises a third electrode on a bottom surface of the conductive connector, and
wherein the third electrode and the common electrode pad of the substrate are connected by a second solder.

10. The display module according to claim 1, wherein the first electrode of the light emitting diode and the first pad of the substrate are connected by a first nano-carbon material,
wherein the display module further comprises a third electrode on a bottom surface of the conductive connector, and
wherein the third electrode and the common electrode pad of the substrate are connected by a second nano-carbon material.

11. A method of manufacturing a display module, the method comprising:
providing an adhesive layer on a first surface of a substrate;
transferring a light emitting diode onto the adhesive layer;
transferring a conductive connector onto the adhesive layer;
connecting a first electrode of the light emitting diode to a first pad of the substrate and connecting a third electrode to a common electrode pad of the substrate, the third electrode being on a bottom portion of the conductive connector, and the connecting the first electrode and the connecting the third electrode comprising heat-pressing the light emitting diode and the conductive connector to the substrate; and
forming a conductive layer on the adhesive layer, wherein a light emitting surface of the light emitting diode is exposed from the conductive layer, and the conductive layer connects a second electrode of the light emitting diode and a fourth electrode, the fourth electrode being on a side surface of the conductive connector.

12. The method according to claim 11, wherein the forming the conductive layer comprise:
providing a liquid conductive ink between the light emitting diode and the conductive connector; and
curing the liquid conductive ink.

13. The method according to claim 11, wherein the forming the conductive layer comprises:
coating a conductive member on the light emitting diode, the conductive connector, and the adhesive layer; and
exposing the light emitting surface of the light emitting diode by removing a portion of the conductive member on the light emitting surface of the light emitting diode, and
wherein the conductive member includes a conductive paste or a conductive film.

14. The method according to claim 13, wherein the removing the portion of the conductive member comprises removing the portion of the conductive member by plasma etching or laser etching.

15. The method according to claim 13, wherein the forming the conductive layer comprises:
covering the light emitting diode, the conductive connector, and the adhesive layer with a photosensitive conductive ink; and
exposing the light emitting surface of the light emitting diode by removing a portion of the photosensitive conductive ink on the light emitting surface of the light emitting diode by photolithography.

16. A display module comprising:
a substrate comprising a first pad and a common electrode pad;
a light emitting diode comprising a first electrode connected to the first pad;
a conductive connector connected to the common electrode pad;
an adhesive layer on the substrate; and
a conductive layer on the adhesive layer, the conductive layer connected to a side surface of the light emitting diode, the side surface being between a light emitting surface of the light emitting diode and a bottom surface of the light emitting diode, the bottom surface being opposite to the light emitting surface,
wherein the side surface of the light emitting diode is connected to the common electrode pad of the substrate by the conductive layer and the conductive connector.

17. The display module according to claim 16, wherein a level of the light emitting surface of the light emitting diode is the same as a level of a top surface of the conductive layer.

18. The display module according to claim 16, wherein the adhesive layer comprises an anisotropic conductive film comprising a black color.

19. The display module according to claim 16, wherein the adhesive layer comprises a non-conductive film comprising a black color.

20. The display module according to claim 16, wherein the light emitting diode and the first pad of the substrate are connected by a first solder, and
wherein the conductive connector and the common electrode pad of the substrate are connected by a second solder.
